(19) United States
(12) Patent Application Publication
(10) Pub. No.: US 2008/0000521 A1
(43) Pub. Date: Jan. 3, 2008

(54) Low-temperature doping processes for silicon wafer devices

(76) Inventors: Siva Sivoththaman, Waterloo (CA); Mahdi Farrokh-Baroughi, Kitchener (CA)

Correspondence Address: Gowling Lafleur Henderson LLP;Suite 1600, 1 First Canadian Place, 100 King Street West, Toronto, ON, M5X 1G5, CA

(21) Appl. No.: 11/798,584

(22) Filed: May 15, 2007

Related U.S. Application Data
(60) Provisional application No. 60/799,990, filed on May 15, 2006.

(51) Int. Cl. H01L 31/04; H01L 21/20

(52) U.S. Cl. 136/254; 438/509; 257/E21.09

(57) ABSTRACT

A low temperature method and system configuration for depositing a doped silicon layer on a silicon substrate of a selected grade. The silicon substrate for functioning as a light absorber and the doped silicon layer for functioning as an emitter. The method comprises the acts of: positioning the silicon substrate in a chamber suitable for chemical vapour deposition of the doped silicon layer on the silicon substrate, an external surface of the silicon substrate suitable for promoting crystalline film growth; using a plurality of process parameters for adjusting growth of the doped silicon layer, the plurality of process parameters including a first process parameter of a process temperature for inhibiting diffusion of dopant atoms into the external surface of the silicon substrate, and a second process parameter of a hydrogen dilution level for providing excess hydrogen atoms to affect a layer crystallinity of the atomic structure of the doped silicon layer; exposing the external surface of the silicon substrate in the chamber to a vapour at appropriate ambient chemical vapour deposition conditions, the vapour including silicon atoms, dopant atoms and the excess hydrogen atoms, the atoms for use in growing the doped silicon layer; and originating growth of the doped silicon layer on the external surface to form an interface between the doped silicon layer and the silicon substrate, such that the doped silicon layer includes first atomic structural regions having a higher quality of the layer crystallinity next to the interface with adjacent second atomic structural regions having a lower quality of the layer crystallinity with increasing concentrations of crystal defects for increasing thickness of the doped silicon layer from the interface. The resultant silicon substrate and doped layer (or thin film) can be used in solar cell manufacturing.

This application claims the benefit of U.S. Provisional Application No.: U.S. 60/799,990, filed May 15, 2006, herein incorporated in entirety by reference.

### FIELD OF THE INVENTION

The present invention relates processes for the production of silicon thin films and silicon wafer devices.

### BACKGROUND

The need for the use of environment-friendly, sustainable energy technologies continues to grow by the day. Photovoltaics (PV) are an attractive form of energy conversion technology where sunlight is directly converted into electrical energy. While PV is considered one of the fastest growing industries in the renewable energy sector, there are still challenges in making PV affordable, i.e., in rendering it cost-competitive as opposed to conventional fossil-fuel-based electricity. Partly influenced by the diverse electricity tariff policies exercised by different countries, the current cost of PV electricity is approximately 2-4 times more expensive compared to conventional electricity. A vibrant market has so far helped to considerably reduce the cost of PV. An average market growth of over 30% translates into a 5% cost reduction per year on a system level. While the PV market continues to grow, the need to further reduce the cost of PV to achieve affordability persists. Wafer-based crystalline silicon (Si) solar cells dominate 90-95% of the PV market. In crystalline Si-based commercial PV modules, the material cost itself (poly-Si feedstock, ingot growth, and wafering) is responsible for 40%-50% of the cost, while the cell fabrication and module assembly are each responsible for 25%-30% of the cost. The use of base Si materials produced by low-cost means, efficient device designs, and development of compatible device processing technologies hold the keys to meet the challenge of cost reduction.

In addition to affordability, another important challenge that is facing current PV manufacture is the expected shortage of Si feedstock in the near future. Until recently, the Si feedstock needs of the solar cell manufacturers have been sufficiently met by the off-spec silicon from the IC (integrated circuits) industry. However, due to the steady and continued growth of the PV industry, the Si supply for PV will now lag behind the demand. The PV Si supply in 2006 was about 20,000 tons. It is predicted that, already in 2007, the rapid growth of PV manufacture will be truncated by insufficient supply of Si. Several industries worldwide have started to respond to this problem in recent years through production initiatives for PV-specific Si. Various methods are being applied to produce Si wafers in less expensive ways. With the electronic quality of the low-cost Si somewhat inferior to that of traditional microelectronic grade Si, challenges arise in developing new fabrication technologies for solar cells that are suitable with low-cost (low-quality) silicon wafers/substrates (e.g. such as low grade IC silicon) in order not to compromise device performance of the produces silicon wafer solar cell devices.

Current conventional fabrication technologies for Si solar cells involve several high temperature (HT) steps, normally carried out at more than 900° C. Typical HT steps include; emitter diffusion, back surface field formation (BSF), and surface passivation. Depending on the complexity of the Si wafer device, there can also be multiple diffusions (selective emitters, localized BSF, point contacts) and oxidations (passivation oxide, anti-reflection coatings, masking oxides) at HT. The Si device performance largely depends on the minority carrier lifetime in the Si wafers, i.e. wafer/substrate grade. In order to maintain a high carrier lifetime in Si, the use of defect-free Si substrates/wafers of good quality, stringent wafer-cleaning requirements involving large quantities of chemicals, and clean process ambient are very critical in HT processes. High performance Si solar devices have been demonstrated at laboratory level using high-grade quality Float Zone (FZ) and Czochralski (CZ) Si wafers of both n-type and p-type. Generally, high efficiency PV systems can be too expensive for extensive use and application in solar cell markets.

In the drive towards cutting the cost of PV, several methods have been introduced for producing PV-specific Si wafers by less expensive means compared to traditional microelectronic grade Si. Examples include multi-crystalline Si by direct casting, Si ribbon growth, and Si sheets from powder. Further, with the scarcity of Si for PV fast becoming an issue, manufacturers have started exploring new method Si production using Si substrate feedstock refined at different levels of purity. With the presence of impurities and crystal defects in considerable amounts in lower grade SI substrates, traditional HT device processing techniques may not be ideal for these materials since multiple thermal excursions at HT processing can further degrade the substrate material quality (rendering the resultant solar cell either substandard or otherwise insufficient for PV systems). Further, pre-process defect passivation techniques, such as hydrogenation, need to be applied to the wafers to improve the material quality. Again, HT process steps can remove the advantages brought about by the passivation techniques. Therefore, low temperature (LT) device processing technologies need to be resorted to in order to maintain the material cost advantage and device performance. A minimal thermal budget will also remove the stringent requirements for cleaning and chemical usage, as well as the thermal stress introduced to the substrate.

A current LT approach for Si solar cells is the hetero-junction technology. In this technology, amorphous Si (a-Si) films are deposited on crystalline Si substrates at LT. The junction (e.g. np) thus formed turns out to be a hetero-junction (i.e. amorphous-crystalline), as opposed to classical homo-junctions (i.e. crystalline-crystalline) created by HT diffusion processes, due to the difference in band gap between the a-Si emitter film and the crystalline Si (c-Si) substrate. A solar cell structure based on the LT technology is the so-called “hetero-junction with intrinsic layer” device. This device employs both intrinsic and extrinsic a-Si films. Since a-Si has low carrier mobility and electrical conductivity (due to lack of crystallinity), the devices always require additional transparent conductive oxide (TCO) films on top of a-Si to enable electrical conduction without resistive losses. The requirement of TCO films can add to process complexity and cost. Further, the interface quality between the a-Si film and the c-Si substrate is very critical for the hetero-junction structure. In order to achieve a better interface, the hetero-junction device processes employ an ultra-thin (5-10 nm), intrinsic (undoped) a-Si film deposited prior to the deposition of doped a-Si film. These requirements, in addition to increasing the number of process steps and complexity, can also add stringent condition complications for process control. Further, it is recognised that the use of amorphous Si in the emitter layers is disadvantageous, due to the low doping efficiencies of amorphous Si (a-Si) films.

As is generally known from industry, researchers have so far been unsuccessful in developing low temperature Si thin films that have desired levels of crystal quality, doping efficiency, and conductivity. The advantages of such low temperature Si thin films can be low temperature Si solar cell manufacturing technologies that are simpler, that inhibit process complexities like TCO layers and interface passivation, and that result in pn junctions that are of sufficient high quality providing desired high performance levels of the solar cells.

Further, it is recognized that deposition temperature can play an important role in determining the crystallinity quality of Si thin films. In the case of chemical vapor deposition (CVD) deposition of Si thin films on crystalline Si substrates, higher film crystallinity typically requires HT deposition conditions, which enhances surface migration of the dopant as well as Si atoms. In the case of low temperature techniques such as plasma enhanced chemical vapor deposition, LT depositions typically result in amorphous and some times micro or nano crystalline Si films. Further, the attempt of adding dopant atoms (e.g. boron and/or phosphorous) in the thin-film growth process can make it even more difficult to achieve sufficient crystallinity of the doped thin film at LT. Therefore, in Si solar cells, the LT requirement for processing and the requirement for depositing highly crystalline/conductive films have been difficult to achieve simultaneously.

Current low temperature Si cell fabrication processes have complexities associated with the need for transparent conductive oxides, the need for ultra-thin emitters, and the need for ultra-thin intrinsic buffer layers. Developing low temperature silicon solar cells without these complexities has not been possible since highly conductive Si emitters (e.g. with conductivities close to 1000 Ω⁻¹ cm⁻¹) with high crystallinity have not been possible to develop.

### SUMMARY OF THE INVENTION

It is an object of the present invention to provide fabrications systems and methodologies for producing silicon based thin films that obviate or mitigate at least some of the above-presented disadvantages.

Another objective of the present invention is to develop a silicon thin film at low temperature, that inhibits dopant diffusion into the substrate, with desired film conductivity and crystallinity and to develop new low-temperature silicon solar cell process sequences using this film.

Another objective of the present invention is to provide a process for depositing Si thin films in a low temperature CVD process with dopant precursor gases resulting in desired doping efficiencies comparable to those obtainable by high temperature fabrication processes.

Current low temperature Si cell fabrication processes have complexities associated with the need for transparent conductive oxides, the need for ultra-thin emitters, and the need for ultra-thin intrinsic buffer layers. Contrary to the current state of the art, there is provided a low temperature method and system configuration for depositing a doped silicon layer on a silicon substrate of a selected grade. The silicon substrate for functioning as a light absorber and the doped silicon layer for functioning as an emitter. The method comprises the acts of: positioning the silicon substrate in a chamber suitable for chemical vapour deposition of the doped silicon layer on the silicon substrate, an external surface of the silicon substrate suitable for promoting crystalline film growth; using a plurality of process parameters for adjusting growth of the doped silicon layer, the plurality of process parameters including a first process parameter of a process temperature for inhibiting diffusion of dopant atoms into the external surface of the silicon substrate, and a second process parameter of a hydrogen dilution level for providing excess hydrogen atoms to affect a layer crystallinity of the atomic structure of the doped silicon layer; exposing the external surface of the silicon substrate in the chamber to a vapour at appropriate ambient chemical vapour deposition conditions, the vapour including silicon atoms, dopant atoms and the excess hydrogen atoms, the atoms for use in growing the doped silicon layer; and originating growth of the doped silicon layer on the external surface to form an interface between the doped silicon layer and the silicon substrate, such that the doped silicon layer includes first atomic structural regions having a higher quality of the layer crystallinity next to the interface with adjacent second atomic structural regions having a lower quality of the layer crystallinity with increasing concentrations of crystal defects for increasing thickness of the doped silicon layer from the interface.

An aspect provided is a low temperature method for depositing a doped silicon layer on a silicon substrate of a selected grade, the silicon substrate for functioning as a light absorber and the doped silicon layer for functioning as an emitter; the method comprising the acts of: positioning the silicon substrate in a chamber suitable for chemical vapour deposition of the doped silicon layer on the silicon substrate, an external surface of the silicon substrate suitable for promoting crystalline film growth; using a plurality of process parameters for adjusting growth of the doped silicon layer, the plurality of process parameters including a first process parameter of a process temperature for inhibiting diffusion of dopant atoms into the external surface of the silicon substrate, and a second process parameter of a hydrogen dilution level for providing excess hydrogen atoms to affect a layer crystallinity of the atomic structure of the doped silicon layer; exposing the external surface of the silicon substrate in the chamber to a vapour at appropriate ambient chemical vapour deposition conditions, the vapour including silicon atoms, dopant atoms and the excess hydrogen atoms, the atoms for use in growing the doped silicon layer; and originating growth of the doped silicon layer on the external surface to form an interface between the doped silicon layer and the silicon substrate, such that the doped silicon layer includes first atomic structural regions having a higher quality of the layer crystallinity next to the interface with adjacent second atomic structural regions having a lower quality of the layer crystallinity with increasing concentrations of crystal defects for increasing thickness of the doped silicon layer from the interface.

A further aspect provided is a silicon wafer device including a doped silicon layer on a silicon substrate of a selected grade, the silicon substrate for functioning as a light absorber and the doped silicon layer for functioning as an emitter; the device comprising: an internal surface of the silicon substrate from which originates the doped silicon layer to form an interface between the doped silicon layer and the silicon substrate, such that doped silicon layer includes first atomic structural regions having a higher quality of layer crystallinity next to the interface with adjacent second atomic structural regions having a lower quality of said layer crystallinity with increasing concentrations of crystal defects for increasing thickness of the doped silicon layer from the interface.

### BRIEF DESCRIPTION OF DRAWINGS

These and other features of the present invention will become more apparent in the following detailed description in which reference is made to the appended drawings by way of example only, wherein:

FIG. 1 is a schematic diagram of a silicon solar cell fabricated using high temperature processes;

FIG. 2a is a schematic diagram of a double-sided, low-temperature hetero-junction solar cell employing an amorphous silicon/crystalline silicon hetero-junction;

FIG. 2b is the single-sided version of the hetero-junction cell of FIG. 2a;

FIG. 3 is the high-resolution transmission electron microscope (HRTEM) image of the atomic structure of a hydrogenated amorphous silicon film deposited on a crystalline silicon substrate of FIGS. 2a and 2b;

FIG. 4 is a diagram of a low temperature silicon wafer device fabrication environment;

FIG. 5 is a further HRTEM image closeup of the bulk of the doped layer of FIG. 12b showing the atomic arrangement;

FIG. 6 shows conductivity of the doped layers of the environment of FIG. 4 evolving with different hydrogen dilution (HD) levels;

FIG. 7a shows the UV Raman spectra of the as-deposited doped layer formed by the environment of FIG. 4;

FIG. 7b shows a further embodiment of the UV Raman spectra of FIG. 7a;

FIG. 8a shows current-voltage-temperature (I-V-T) diode characteristics of the doped layer formed by the environment of FIG. 4;

FIG. 8b shows the saturation currents (I_{O1}, I_{O2}) and activation energies (EA) extracted from FIG. 8a;

FIG. 9a shows the flow chart for an “LT Process I” of the system of FIG. 4;

FIG. 9b is the process sequence of an “LT Process II” of the system of FIG. 4;

FIG. 9c represents the process sequence for an “LT Process III” of the system of FIG. 4;

FIGS. 10a, 10b, 10c represent the schematic of the solar cell devices fabricated using the LT Process I, LT Process II, and LT Process III of FIGS. 9a,b,c respectively;

FIG. 11 shows the current-voltage characteristic of a test solar cell device (1 cm²) fabricated using LT Process I to demonstrate the high fill factor (75%) of the device without using transparent conductive oxides;

FIG. 12a is a TEM image of a low-temperature silicon based emitter layer deposited on a crystalline Si substrate using the fabrication environment of FIG. 4;

FIG. 12b is a closeup HRTEM image of the image of FIG. 12a;

FIG. 12c is a closeup HRTEM image of a further embodiment of the image of FIG. 12b;

FIG. 13 is a block diagram of a computing device of the fabrication environment of FIG. 4;

FIG. 14 is an example silicon wafer device fabricated using the environment of FIG. 4; and

FIG. 15 is an example fabrication process of the system of FIG. 4.

### DETAILED DESCRIPTION OF THE PREFERRED EMBODIMENTS

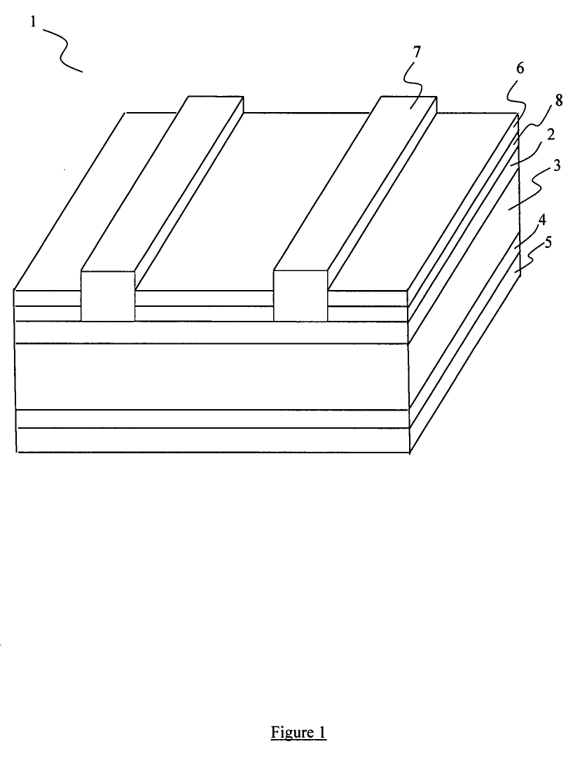

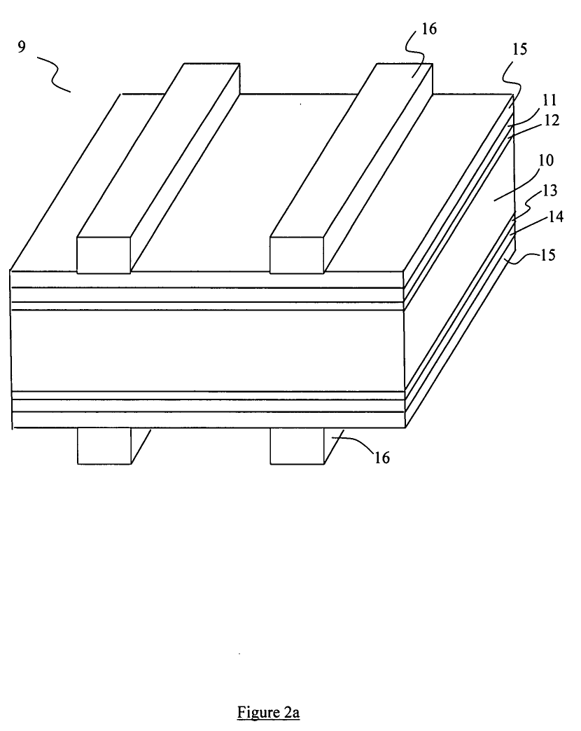

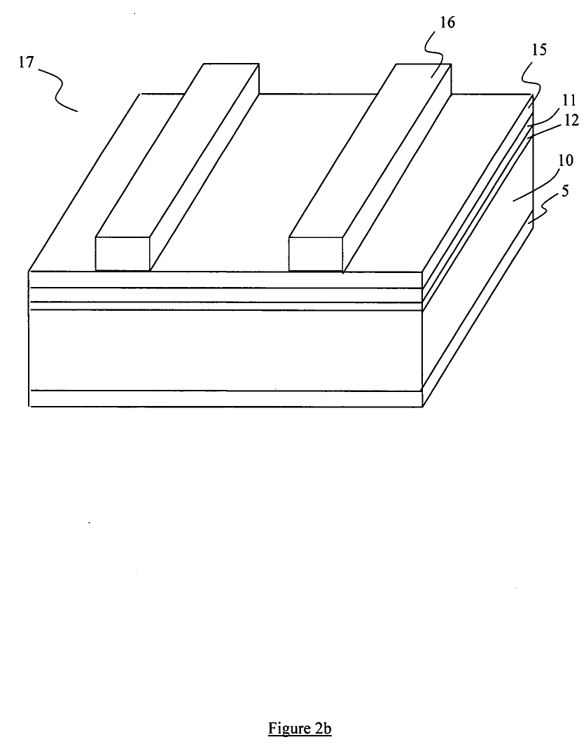

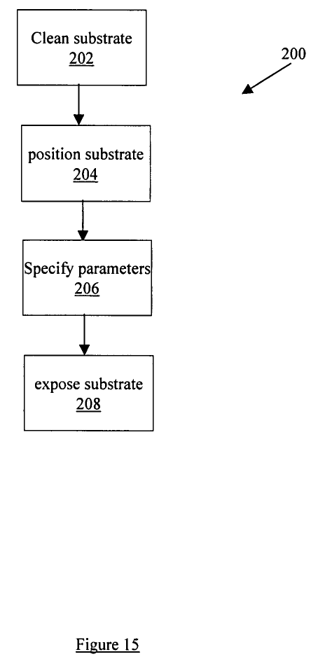

A Low Temperature (LT) fabrication scheme 200 (see FIG. 15) for silicon wafer devices 21 (see FIG. 14) is described, with the resulting crystal structure of the devices 21 including a silicon substrate 22 attached to a grown thin film layer 23 (silicon based), thereby defining an interface 114. It is recognized that the fabrication scheme can be used for manufacturing a number of different silicon wafer devices 21 for differing technology applications, such as but not limited to photovoltaic cells used in manufacturing of solar systems for the conversion of sunlight into electrical energy. It is recognized that the fabrication scheme 200, and resultant silicon wafer device 21 structure, are different from other High Temperature (HT) and other LT fabrication schemes and their corresponding silicon wafer devices 1, 9, 17 (see FIGS. 1, 2a, 2b).

Solar Cell Examples

Referring to FIG. 1, shown is an example wafer structure of a HT processed conventional n⁺pp⁺ silicon solar cell 1. The conventional silicon solar cell 1 can comprise a high-temperature diffused crystalline silicon emitter 2, a crystalline silicon absorber 3, a high temperature diffused back surface field (BSF) structure 4, backside metal contact and reflector 5, a single or double layer anti-reflective coating 6, front metal grid 7, and a high temperature oxide passivation layer 8. This solar cell 1 owes its success largely to the quality of the junction between the n⁺ emitter 2 and the p-type silicon absorber substrate 3, for example. The n⁺ emitter 2 is formed by diffusion of normally phosphorous (it is recognized that an analogous p-type emitter 2 could be formed using boron in place of the phosphorous when using an n-type silicon substrate 3) in the silicon substrate 3 at high temperatures, normally more than 900° C. Facilitated by the diffusion of dopant donor atoms inside the crystalline silicon substrate 3, the metallurgical junction can be formed inside (i.e. beneath the interface 0 between the substrate 3 and the emitter 2) the substrate 3 of the silicon wafer device 1, hence helping to provide a high quality pn junction diode (e.g. an example of the silicon wafer device 1). The emitter 2 layer is usually greater that 0.5 microns in thickness, and absorbs light in the short wavelength (blue) region. To reduce the recombination of minority holes at the emitter 2 surface, the oxide passivation film 8 is grown at temperatures greater than 900° C. In order to reduce the recombination of minority electrons on the rear surface of the silicon substrate 3, the p⁺ back surface field 4 is created at the rear surface by diffusing boron at high temperatures, usually more than 950° C. It is recognized that manufacturing of the silicon wafer device 1 involves multiple steps using process temperatures in excess of 900° C.

Referring to FIGS. 2a and 2b, a low temperature (LT) alternative for the solar cell 1 of FIG. 1 is based on a hetero-junction between hydrogenated amorphous silicon (a-Si:H) of an emitter layer 11 and crystalline silicon materials of a substrate 10. FIG. 2a illustrates the schematic structure of a double-sided hetero-junction solar cell 9. This is referred to as the “HIT” solar cell structure. In this structure, the n-type crystalline silicon substrate 10 is used as the absorber and the very thin (5-10 nm), boron doped (p⁺), a-Si:H emitter layer 11 is used as the emitter. The emitter layer 11 is deposited using plasma enhanced chemical vapor deposition (PECVD) deposition at low temperature. Prior to this emitter layer 11 deposition, an intrinsic (undoped) a-Si:H layer 12 is employed to help improve the quality of the junction between the highly boron-doped a-Si:H emitter layer 11 and the n-type c-Si substrate 10. It should be noted that unlike the high temperature-diffused solar cell device 1 (see FIG. 1), the metallurgical junction in the solar cell 9 is formed on the surface of the substrate 10 (between substrate 10 and layer 12), which initially was full of dangling bonds with density of more than 10¹⁵ cm⁻², for example. Therefore, an optimized surface treatment by the ultra-thin (<about 5 nm) intrinsic a-Si:H layer 12 has been shown to be effective in passivating the dangling bonds on the surface of silicon substrate 10. It is noted that the inclusion of the intrinsic layer 12 is a critical step to help the compatibility between the substrate 10 and the amorphous silicon (a-Si:H) emitter layer 11. Further, a back surface field structure is also implemented by using an ultra thin intrinsic a-Si:H 13 and a phosphorous-doped (n⁺) a-Si:H film 14. Since the conductivities of the doped a-Si:H film 14 and the doped emitter layer 11 are low, transparent conductive oxide (TCO) films 15 are employed on both sides of the solar cell 9 to collect photo-generated carriers in the absorber layer (i.e. silicon substrate 10). Further, top and bottom metal grid patterns 16 are employed on top of the TCO layers 15, hence it is recognized that the TCO layers 15 are interposed between the grid patterns 16 and the doped a-Si:H layers (e.g. emitter layer 11 and film 14).

Referring to FIG. 2b, shown is a single-sided version of the HIT solar cell 17 without using back surface field structure at the rear side of the device 17. The light absorber silicon substrate 10 can be an “n” or “p” type, with the emitter layer 11 being “p” or “n” type accordingly. It is recognized that all of the low temperature hetero-junction silicon solar cells (i.e. having a crystalline substrate 10 combined with amorphous silicon emitter layers 11, and/or films 14) rely on the high electrical conductivity of the TCO layers 15 for collection of the photo-generated carriers by the metal grid patterns 16.

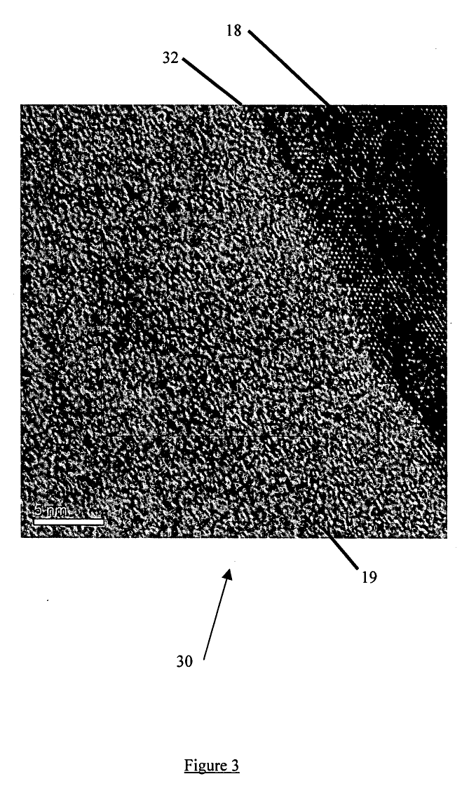

Referring to FIG. 3, shown is a high-resolution transmission electron microscope (HRTEM) image 30 of a low-temperature Si film 19 developed by using a standard RF PECVD system (e.g. plasmatherm 790). The atomic structure of a hydrogenated amorphous silicon film 19, deposited on a crystalline silicon substrate 18, shows the clear contrast in atomic structure between the film 19 (non-crystalline) and the substrate 18 (e.g. the lack of epitaxial growth in the film 19 inherited from the substrate 18 crystalline structure). It is recognized that the presence of amorphous atomic structure in the film 19 hinders any propagation (e.g. epitaxially) of the crystal structure of the substrate 18 into the atomic structure of the film 19. It is recognized that epitaxial growth can be defined as thin film 19 atomic structure that has the same or similar crystalline orientation as the substrate 18 on which the thin film 19 is grown, of which the thin film 19 shown in FIG. 3 has no discernable epitaxial growth.

For example, the HRTEM image 30 is of the fifteen nm, phosphorous-doped (n-type) a-Si:H film 19 that is deposited on the p-type crystalline-Si substrate 18. As shown in the picture, an interface 32 between the c-Si substrate 18 and the a-Si:H emitter 19 is very sharp and the material phases are completely different in the emitter 19 and in the substrate 18. For example, the conductivity of the (n-type) a-Si:H emitter 19 shown in FIG. 3 is less than 0.01 Ω⁻¹cm⁻¹, due to the lack of crystalline atomic structural quality of the amorphous Si material. The conductivity of this emitter 19 film is low because free carrier mobility, here electrons, in the a-Si:H emitter 19 film is low (in the order of 1 cm²/v/s), and also the doping efficiency of the emitter 19 film is very low (in the order of 1%). Such a low conductivity can result in a sheet resistance in the range of several tens of mega-ohms per square for the emitter 19 film of fifteen nm thickness. This is one reason why the solar cells of FIGS. 2a and 2b use the TCO layers 15 on top of their emitter layers.

Low Temperature Fabrication Environment 100

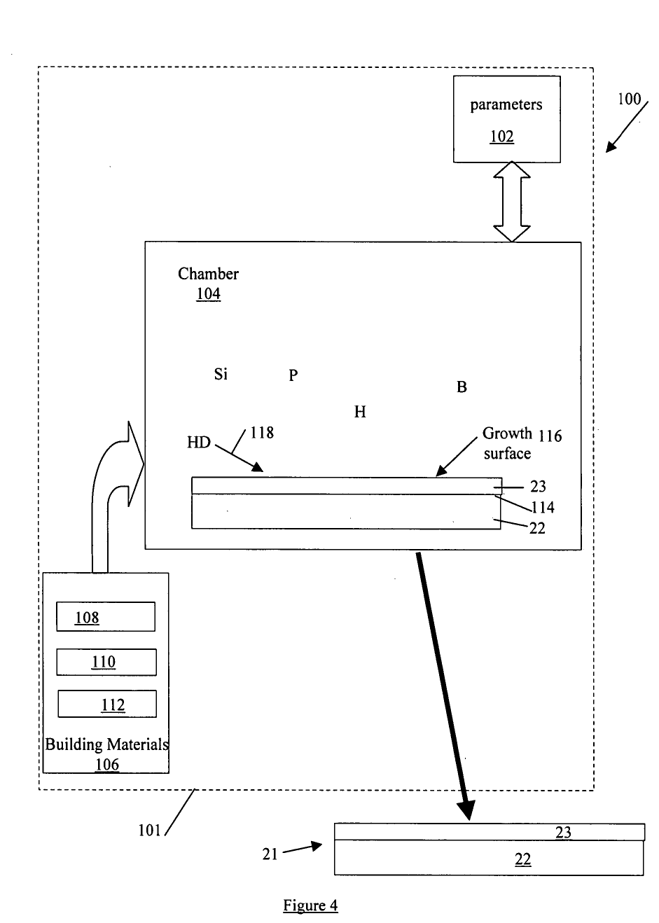

Referring to FIG. 4, shown is a low temperature fabrication environment 100 for fabricating the silicon wafer devices 21, having a crystalline Si substrate 22 (doped or undoped) connected/attached directly to a grown thin film doped layer 23 (silicon based), thereby defining an interface 114 (e.g. pn junction). The fabrication environment 100 can be implemented using a deposition chamber 104 (e.g. PECVD or HWCVD) controlled by a computing system 101 (e.g. a plasmatherm 790 machine). The operation of the chamber 104 is done through specifying a number of process control parameters 102, in order to influence the growing conditions (e.g. growth rate, atomic composition, degree of doping, degree of crystallinity, thickness, etc.) of a growth surface 116 of the emitter layer 23.

For example, the environment 100 can be a plasma enhanced chemical vapor deposition (PECVD) process applied with appropriate precursor gases (layer building materials 106) for supplying silicon atoms Si, dopant atoms P,B and the excess hydrogen atoms H, the atoms for use in growing the doped silicon emitter layer 23. The process control parameters 102 are monitored in order to deposit the doped silicon emitter layer 23 (e.g. thin films) of sufficient epitaxial quality on the Si substrates 22. The process is so designed that high carrier mobility, electrical conductivity, and crystallinity can be obtained in the thin films, even when the deposition temperature is kept low, as further described below.

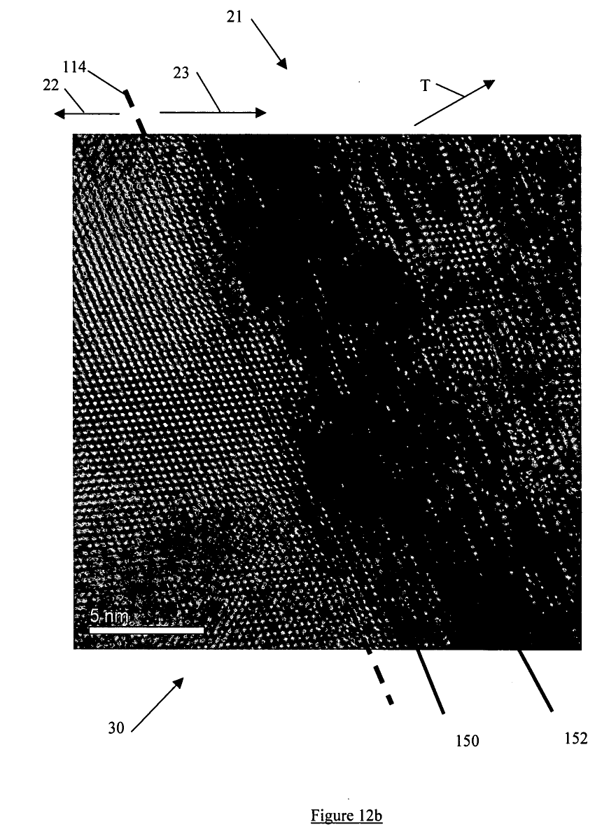

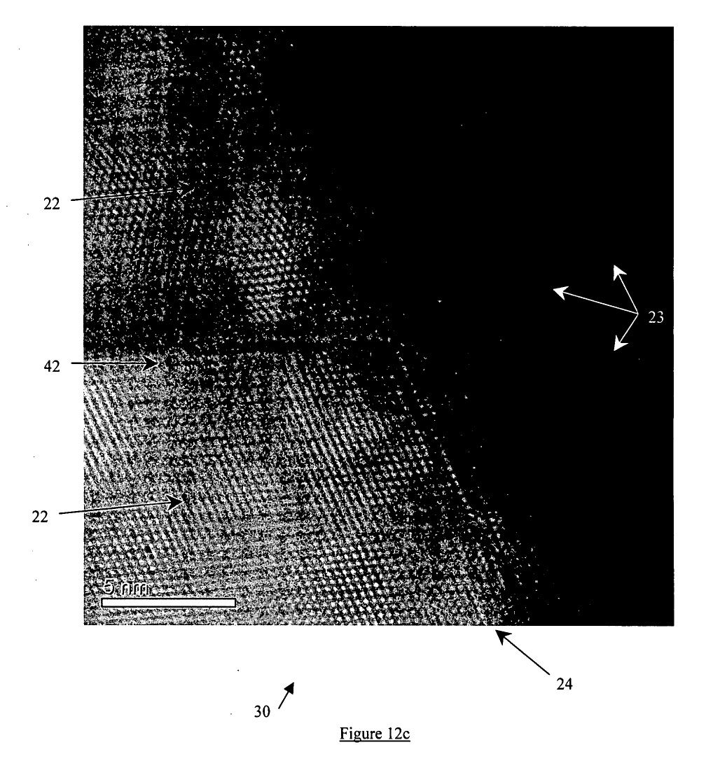

More specifically, the environment 100 can be used to fabricate the silicon devices 21 in a low temperature (e.g. less than 450° C.) PECVD process that inhibits dopant diffusion into the substrate 22. Referring to FIG. 12b, the deposition process on the growth surface 116 (see FIG. 4) allows the growth of the doped emitter layer 23 starting off, or otherwise originating, on the external surface 114 to form a uniform atomic structural interface region 150 (see FIG. 12b) (as compared to the interface 32—see FIG. 3) between the doped silicon layer 23 and the silicon substrate 22, such that doped silicon layer 23 includes first atomic structural regions 150 having a higher quality of the atomic crystallinity next to the represented external surface 114 with adjacent second atomic structural regions 152 having a lower quality of the layer crystallinity with increasing concentrations of crystal defects for increasing thickness T of the doped silicon layer 23.

The regions 150, 152 include a propagation of the substrate 22 crystal structure into the crystallinity of the doped emitter layer 23. This layer crystallinity in the regions 150, 152 can include epitaxial growth inherited from the substrate 22 crystal structure. Further, the crystal orientation of the substrate 22 crystal structure can be similar to the crystal orientation of the doped layer 23 crystallinity.

Referring again to FIG. 4, for an n-doped Si film process, precursor gases/vapours used can be such as but not limited to: silane (SiH4) as a silicon atomic source 108; phosphine (PH3) as a dopant atomic source 110; and hydrogen (H2) as a hydrogen dilution level source 112 for providing excess hydrogen atoms. The controlled amounts of hydrogen (H2) (as one of the process parameters 102) as a hydrogen dilution level source 112 are used by the environment 100 to partially control the crystallinity of the deposited layer 23. It is also recognized that for p-doped Si film processes, diborane can be used as the dopant atomic source 110.

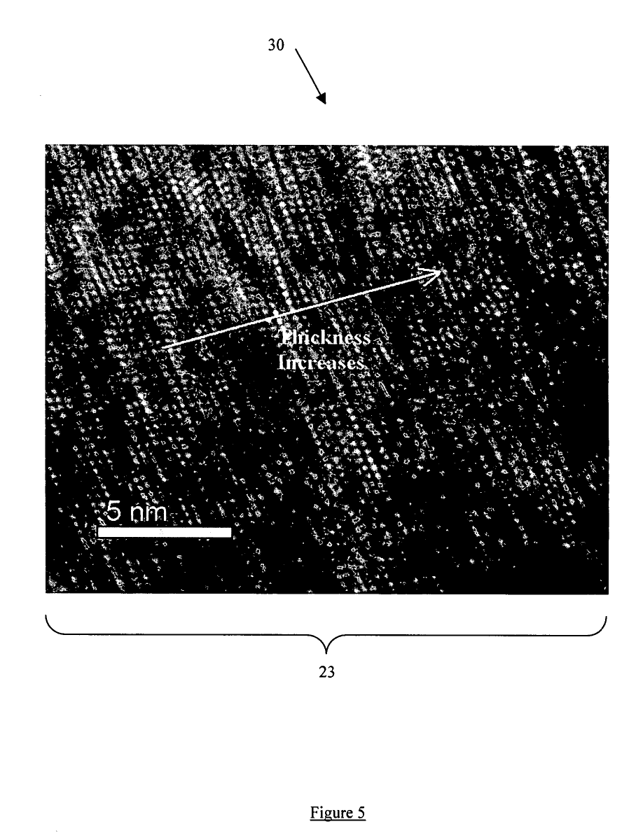

Referring again to FIG. 12b, the doped layer 23 Si material exhibits desired high crystallinity and high conductivity. The higher crystallinity of the doped layer 23 (over that of amorphous layers 11—see FIGS. 2a, 2b and FIG. 3) serves the conductivity of the doped layer 23 in two ways: (i) it improves the carrier mobility, and (ii) it improves the doping efficiency of the dopant atoms in the crystalline-like atomic structure (the ratio of the electrically active phosphorous concentration to the total phosphorous concentration in the film). FIG. 12b shows the HRTEM image 30 of the interface regions 150, 152 between a (n+) layer 32 and the p-type crystalline Si substrate 22. The doped emitter layer 23 was deposited using the PECVD chamber 104 (see FIG. 4) at a process temperature of 300° C. with silane and phosphine precursors diluted in hydrogen (the gas phase phosphine to silane ratio was 1%). As shown in FIG. 12b in the regions 150, 152, the crystalline structure of the doped emitter layer 23 has followed the crystal order of the substrate 22. This results in a highly crystalline (n+) Si doped emitter layer 23. As a result and interestingly enough, there is not a well-defined interface 114 (other than shown representatively for the original growth surface 116 at growth time=0) between the crystalline Si substrate 22 and the doped emitter layer 23. This shows that the crystal order of the substrate 22 has propagated into the doped emitter layer 23 and the atomic arrangement in the doped emitter layer 23 is very similar to the atomic arrangement of the substrate 22. FIG. 5 shows the HRTEM image 30 taken within the bulk of the doped emitter layer 23, such that the image 30 shows that the crystallinity of the film 23, in presence of about 1% phosphorous concentration, is very high and that the material is expected to show high carrier mobility and electrical conductivity due appropriate selection of the process control parameters 102 (see FIG. 4). These facts have been verified experimentally, as further described below.

Control Parameters 102

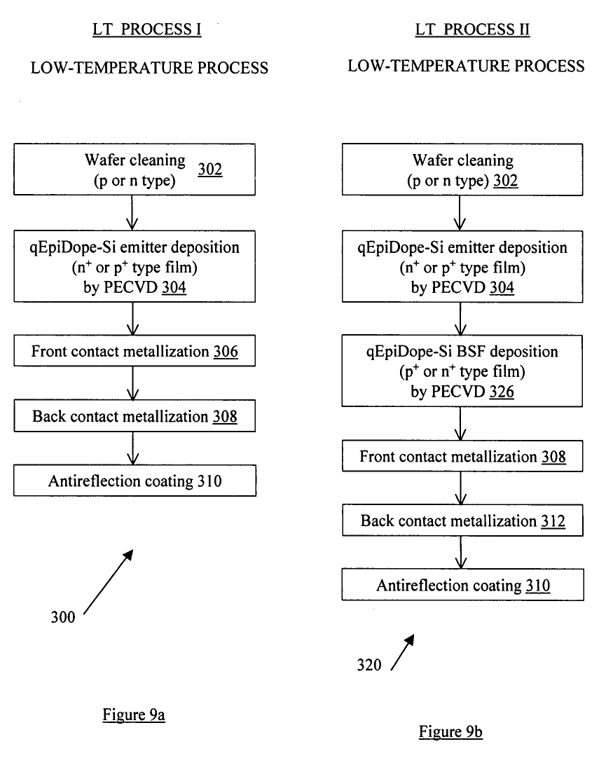

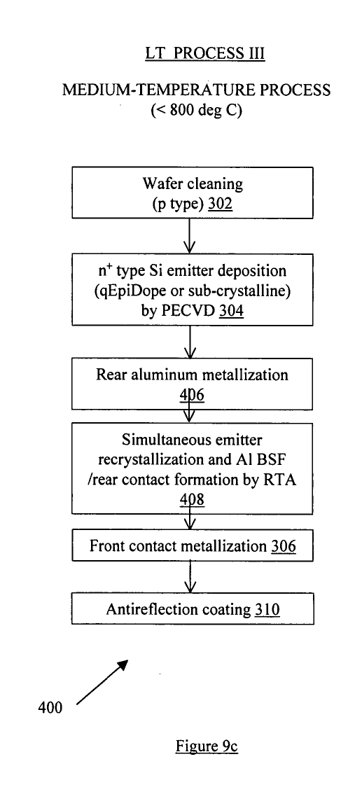

Referring again to FIG. 4, the process control parameters 102 can be adjusted, such as but not limited to: flow rates of the precursor atoms with respect to the growth surface 116; hydrogen dilution (HD) of the precursor gases; plasma RF (radio frequency) power; chamber 104 process pressure; surface treatment (see FIG. 9a) further described below; a soft plasma pre-treatment (see FIG. 9a) further described below; and chamber 104 temperature, in order to achieve the doped silicon emitter layer 23 that starts to grow (e.g. epitaxially) from the external surface 114 of the silicon substrate 22, i.e. at low temperature. The kinetics of doped silicon emitter layer 23 formation, the gradual change in crystallinity of the doped silicon emitter layer 23 for increasing layer 23 thickness, type of bonding of dopant atoms (e.g. P, B), and dopant efficiency can all be affected and controlled using appropriate adjustment of the process control parameters 102. The desired high crystallinity, doping efficiency, and conductivity of the doped silicon emitter layer 23, along with the ability to form electrically high quality pn junctions devices 21 with crystalline silicon substrates 22 are further discussed below.

The n-type doped layers 23 are grown on the substrates 22 using SiH4, PH3, and H2 precursors under proper process conditions specified by the process control parameters 102 (see FIG. 4). A high hydrogen dilution (HD=[100H2/(SiH4+PH3+H2)]) technique with HD more than 90% was employed to get the crystalline character doped layers 23 with desired doping efficiency (represented by conductivity levels—see FIG. 6). The RF power and the process pressure can be chosen, with a reasonably wide process window, such that the emitter layer 23 starts to grow through crystal structure propagation of the crystal structure of the substrate 22. For growing 30-130 nm thick doped layers 23, the process parameters 102 can be specified in the following example process windows: chamber pressure [200 mTorr-1 Torr], the RF power density [10 mW/cm2-70 mW/cm2], and temperature [200° C.-300° C.]. It is recognized that the thickness of the doped silicon layer 23 can be such as but not limited to: equal to or less than 40 nm; equal to or less than 50 nm; equal to or less than 60 nm; equal to or less than 70 nm; equal to or less than 80 nm; equal to or less than 90 nm; equal to or less than 100 nm; equal to or less than 110 nm; equal to or less than 120 nm; or equal to or less than 130 nm, dependent upon the setting of the process parameters 102.

Further, it is recognised that the process temperature of the process parameters 102 for facilitating propagation of the crystal structure of the substrate 22 into the atomic structure of the doped layer 23 can be temperatures such as but not limited to: between 150 and 475 centigrade; between 150 and 450 centigrade; between 150 and 425 centigrade; between 150 and 400 centigrade; between 150 and 375 centigrade; between 150 and 350 centigrade; between 150 and 325 centigrade; between 150 and 300 centigrade; between 150 and 275 centigrade; between 150 and 250 centigrade; between 150 and 225 centigrade; or between 150 and 200 centigrade. Further, the process pressure can be specified in the range of 150 mTorr to 1.1 Torr, the plasma RF power can be specified in the range of 5 mW/cm2 to 75 mW/cm2, the hydrogen dilution level HD can be specified in the range of 80 percent to 99 percent or specified in the range of 85 percent to 95 percent. It is recognized that any combination (or single one thereof) of the control parameters 102 can be used to control the growth rate of the doped silicon layer 23, for example based on the hydrogen dilution level HD.

In one embodiment, for a process temperature of 300 centigrade, the RF power density of 47 mW/cm2 and the process pressure of 400 mTorr can be used with HD values of 80,85,90,95 percent to facilitate propagation of the crystal structure of the substrate 22 into the atomic structure of the doped emitter layer 23.

FIG. 6 shows the measured conductivity 160 of Si thin films developed with different hydrogen dilution (HD) values 165. Two different regimes, a non/low-crystalline phase 170 and a high crystal quality phase 175, can be identified. A transitional region 172 separates these two regimes 170, 175. The films deposited with HD<80% show low conductivity, about 0.008 Ω−1 cm−1, comparable to the conductivity of n-type amorphous Si films. The films grown with HD>85% show very high film conductivities about 680 Ω-1 cm−1, comparable to the conductivity of the highly doped high temperature HT diffused crystalline Si emitters. A somewhat rapid change from low to high conductivity occurs in the HD window of 78%<HD<89% (e.g. transitional region 172). Along with other process parameters 102, HD can play a role in the growth mechanism of the doped emitter layers 23. The conductivity of the doped emitter layers 23 can be varied over 5 orders of magnitude with varying HD. The doped emitter layers 23 belong to the high HD regime. By varying the RF power density and process pressure and keeping the high HD constant it is possible to increase the conductivity of the as deposited doped emitter layers 23 even further. It is possible to obtain very high conductivity exceeding 2000 Ω−1 cm−1 by optimizing the RF power density and process pressure for a HD setting of approximately 90%.

Also shown in FIG. 6, the effect of a rapid thermal anneal 180 as one of the process control parameters 102 on the conductivity of the PECVD (n+) doped emitter layers 23, deposited at low temperature. Based on this experiment all of the doped emitter layers 23, irrespective of HD, the majority of the doped emitter layers 23 show very high conductivities after a short time anneal time (e.g. less than 1 to 2 minutes) at a medium anneal temperature between 700 and 800° C. (e.g. 750° C.). This shows that solid phase (re)crystallization of the doped emitter layers 23 has happened due to the anneal process. The conductivity of the as-deposited doped emitter layers 23 that were initially non-crystalline improved by more than 5 orders of magnitude after the high temperature anneal 180, whereas only a small improvement (few times) in conductivity of the doped emitter layers 23 was brought about by the high temperature anneal 180.

Computer Device 101

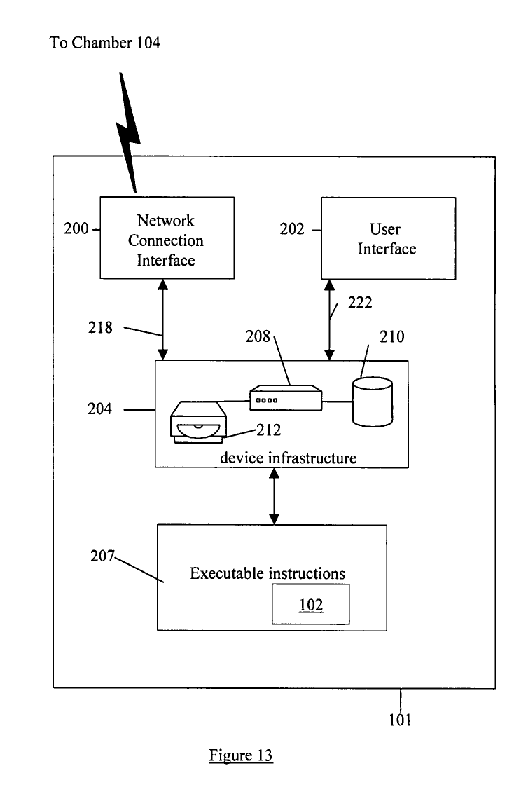

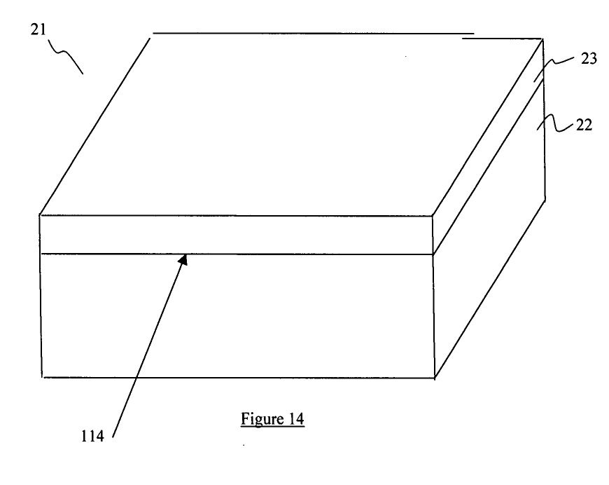

Referring to FIG. 13, the computing device 101 of the environment 100 (see FIG. 4) can include a connection interface 200 coupled via connection 218 to a device infrastructure 204. The connection interface 200 is connectable to the harware systems of the chamber 104 as is known in the art, which enables the devices 101 to control the fabrication process 200 (see FIG. 15), as appropriate.

Referring again to FIG. 13, the device 101 can also have a user interface 202, coupled to the device infrastructure 204 by connection 222, to interact with a user (e.g. chamber 104 operator—not shown). The user interface 202 can include one or more user input devices such as but not limited to a QWERTY keyboard, a keypad, a stylus, a mouse, a microphone and the user output device such as an LCD screen display and/or a speaker. If the screen is touch sensitive, then the display can also be used as the user input device as controlled by the device infrastructure 204.

Referring again to FIG. 13, operation of the device 101 is facilitated by the device infrastructure 204. The device infrastructure 204 includes one or more computer processors 208 and can include an associated memory 210 (e.g. a random access memory). The computer processor 208 facilitates performance of the device 101 configured for the intended task associated with fabrication of the doped emitter layer 23 via the hardware of the chamber 104 (as is known in the art) through operation of the network interface 200, the user interface 202 and other application programs/hardware 207 of the device 101 by executing task related instructions. These task related instructions, including specification of the process control parameters 102 can be provided by an operating system, and/or software applications 207 located in the memory 102, and/or by operability that is configured into the electronic/digital circuitry of the processor(s) 208 designed to perform the specific task(s). Further, it is recognized that the device infrastructure 204 can include a computer readable storage medium 212 coupled to the processor 208 for providing instructions to the processor 208 and/or to load/update the instructions 207. The computer readable medium 212 can include hardware and/or software such as, by way of example only, magnetic disks, magnetic tape, optically readable medium such as CD/DVD ROMS, and memory cards. In each case, the computer readable medium 212 may take the form of a small disk, floppy diskette, cassette, hard disk drive, solid-state memory card, or RAM provided in the memory module 102. It should be noted that the above listed example computer readable mediums 212 can be used either alone or in combination.

Further, it is recognized that the computing device 101 can include the executable applications 207 comprising code or machine readable instructions for implementing predetermined functions/operations including those of an operating system and specification of the control process parameters 102, as well as any feedback sensors (not shown) for communicating (via the interface 202) the state of the fabrication process 200 performed through the chamber 104, for example. The processor 208 as used herein is a configured device and/or set of machine-readable instructions for performing operations as described by example above. As used herein, the processor 208 may comprise any one or combination of, hardware, firmware, and/or software. The processor 208 acts upon information by manipulating, analyzing, modifying, converting or transmitting information for use by an executable procedure or an information device, and/or by routing the information with respect to an output device. The processor 208 may use or comprise the capabilities of a controller or microprocessor, for example. Accordingly, any of the functionality of the chamber 104 and the associated process control parameters 102 may be implemented in hardware, software or a combination of both. Accordingly, the use of a processor 208 as a device and/or as a set of machine-readable instructions is hereafter referred to generically as a processor/module for sake of simplicity. Further, it is recognised that the environment 100 can include one or more of the computing devices 101 (comprising hardware and/or software) for implementing, as desired.

Differences between the Doped Emitter Layer 23 and Other Thin Films

The environment 100 described above leads to highly conductive, doped emitter layers 23 with a desired crystallinity. As the doped emitter layers 23 thickness increases, however, the crystal quality of the doped silicon starts to decrease gradually. Since the doped emitter layers 23 growth was performed at low temperature (e.g. at around 200-350° C.), it may not be feasible to maintain the crystal structure propagation (e.g. epitaxial growth) throughout, i.e. beyond hundreds of nm of doped emitter layer 23 thickness. Observed and measured is a very gradual transition from the epitaxial phase (in the regions 150—see FIG. 12b) tending towards a nano-crystalline phase (in the regions 152) with little to no defined boundaries between the material phases. It is recognised that for device 21 applications requiring smaller film thicknesses (e.g. less that 100 nm), the crystalline phase of the doped emitter layer 23 may never reach the tendency towards the nano-crystalline phase, and therefore can function as a device component with high crystallinity. Overall, the film growth of the doped emitter layer 23 can be described as “quasi-Epitaxial”. Moreover, the regular atomic arrangement at the interfacial region 150 (in the vicinity of the original external surface 114 of the substrate 22 before thin film growth) can facilitate desired quality pn junctions for low-temperature silicon device 21 applications.

In view of the below, doped emitter layer 23 differs from both highly doped high temperature conventional films (obtained by diffusion, ion implantation, and LPCVD) and from low temperature CVD films (amorphous silicon and micro/nano crystalline).

Process Temperature

High quality highly conductive c-Si thin films is obtained using high temperature processes (T>900° C.) such as diffusion of dopants at high temperature, ion implantation and a subsequent thermal anneal and epitaxy of Si thin films by low pressure CVD technique at high temperature. On the contrary, doped emitter layers 23 are obtained at much lower temperature (e.g. T<300° C.) and result in conductivities comparable to the conductivities of the high temperature techniques.

The temperature window at which doped emitter layers 23 are obtained (e.g. 200° C.<T<300° C.) is comparable to the temperature window that traditional doped micro (or nano) crystalline Si thin films can be deposited (100° C.<T<350° C.). However, the electrical and structural properties of the doped emitter layers 23 are completely different from the structural and electrical of doped micro(or nano) crystalline Si films due to help from specification of the process control parameters 102 as described above by example.

Doping Profile and Doping Mechanism:

The doping profile and the structure of the doped emitter layers 23 material is different than the structure of highly doped materials obtained by diffusion, ion implantation, LPCVD techniques at high temperatures and micro(nano) crystalline Si and amorphous Si films at low temperatures, as the doping profile of the doped emitter layers 23 can potentially be uniform throughout the thickness of the film. This is compared to the doping profile obtained by both diffusion and ion implantation, which is nonuniform by nature (normally Gaussian distribution). A further difference is that very abrupt pn junctions (differences in doping character between the substrate 22 and the doped emitter layer 23) are present in the silicon devices 21 manufactured by the environment 100. Although it is possible to grow highly doped high temperature LPCVD c-Si films having uniform doping distributions, it is not possible to obtain very abrupt junctions between the resultant substrate and thin film silicon materials because dopants of the high temperature process tend to diffuse at high temperature and the final distribution of the dopants is different than the grown distribution of dopants.

Further, the doping mechanism and profile in the doped emitter layers 23 is quite different than what is observed in doped amorphous Si and micro(nano) crystalline Si materials. For example, in doped amorphous Si films most of the dopant atoms (about 99%) form 3 fold covalent bonds rather than 4 fold covalent bonds (as in the doped emitter layers 23) and therefore the doped amorphous Si films become electrically inactive. Therefore, the doping efficiency in the doped amorphous Si films is very low. The dopants in micro (or nano) crystalline Si films form mainly 3-fold covalent bonds in amorphous tissues and a combination of 3-fold and 4-fold covalent bonds in the crystallites. Therefore, the doping efficiency is not high in these micro (or nano)crystalline Si films as in the doped emitter layers 23. In doped emitter layers 23, however, because of very high crystallinity of the layer 23, the major portion of dopants in the layer 23 form 4-fold covalent bonds and can result in close to 100% doping efficiency.

Junction

The pn junction obtained between the doped emitter layer 23 and lowly doped Si substrate 22 is different than the junctions obtained between highly doped Si films obtained by diffusion and ion implantation. For example, in the high temperature diffusion and ion implantation processes, the dopants are forced into an existing perfect crystal substrate 22 due to diffusion as a function of the high temperatures. Therefore, the metallurgical junction formed in high temperature is located inside the crystalline substrate, well below the initial substrate surface. This is also partially true for highly doped LPCVD c-Si films grown on lowly doped Si substrate, because dopants tend to diffuse at high temperature and form the interface inside the existing crystalline substrate. On the contrary, in the doped emitter layer 23, however, the doped interface (e.g. pn junction) between the doped emitter layer 23 and the substrate 22 is obtained right at the original external surface 114 of the Si substrate 22 (e.g. prior to growth of the doped emitter layer 23). Accordingly, it can be considered that there is little to no dopant diffusion into the substrate 22 during the growth of the doped emitter layer 23, due to the inhibition of diffusion as a result of the low process temperature (e.g. less that 350 C). Accordingly, this results in a sudden or step change in the dopant distribution across the original external surface 114 location, what can be considered the border between the substrate 22 Si material and the doped emitter layer 23 Si material.

Crystal Structure

The crystal structure of the doped emitter layer 23 is different than the highly doped Si films obtained at high temperature. Crystallinity of the films obtained by diffusion and ion implantation is extremely high, very close to 100%, because dopants are forced into the existing crystalline lattice. Crystallinity of the films obtained by LPCVD is also very high because at high temperatures (about 900 C) pure epitaxy is possible and the crystallinity of the film can be as high as the crystallinity of the c-Si substrate. On the contrary, the crystal structure of the doped emitter layer 23 is not exactly comparable to the crystallinity of the substrate 22. Because of the low temperature nature of the process the doped emitter layer 23 has the best crystallinity in the regions 150 (see FIG. 12b) near the original external surface 114 but the crystallinity of the doped emitter layer 23 gradually decreases with increasing thickness of the film. Nevertheless, the degree of inherited crystallinity of the doped emitter layer 23 is high enough to result in desired degree of doping efficiency and desired degree of free carrier mobility.

Further, the structure of the doped emitter layer 23 is different than the structure of micro (or nano) crystalline Si films. The crystal structure of the micro (or nano) crystalline Si films are inhomogeneous. Grains of different sizes and different orientations are present in throughout the structure of the films, such that none of the crystal structure propagates throughout some of the regions of the film. Also, some amorphous tissues are normally present in the structure of the micro (or nano) crystalline Si films. Further, very sharp grain boundaries or crystallite/amorphous interfaces exist in the structure of the micro (or nano)crystalline films.

Doped emitter layers 23, on the other hand, have a very well defined crystal structure that is inherited from the crystalline substrate 22. The atomic arrangement is very similar to the atomic arrangement of the substrate 22 at the interface 114 and close to the interface regions 150 but far from the interface 114 the atomic arrangement is gradually distorted (i.e. in the regions 152). Rather than sharp grain boundaries observed in micro (or nano) crystalline Si films, we observe very slowly varying crystal planes. This can explain an order of magnitude difference in the mobility of the free carriers in micro (or nano) crystalline Si films and doped emitter layers 23. Accordingly, any crystal structure defects in the regions 150,152 can be such as but not limited to: localized grains of differing sizes; localized grains of differing orientations; presence of sharp grain boundaries; presence of micro or nano crystal structures; stacking faults; edge distortions; and metallic impurities. For example, the layer 23 crystallinity can transition from an epitaxial phase adjacent to the interface 114 to a nano-crystalline phase in the direction of increasing thickness of the doped silicon layer 23.

Referring to FIGS. 12a and 12c, another important outcome of the HRTEM analysis is that the quality of the crystal structure in the doped emitter layer 23 decreases gradually at higher thickness of the doped emitter layer 23 and a larger density of crystal defects, e.g. stacking faults and edge dislocations, can be observed at increasing thickness from the interface 114. Since the doped emitter layer 23 growth was performed at low temperature, it may not be possible to obtain a perfect epitaxial growth. FIG. 12a is a TEM picture of a 100 nm doped emitter layer 23 on (p) mc-Si substrate 22. Further TEM analysis, shown in FIG. 12a, clearly points out to this argument and shows that the crystal quality at higher emitter thickness (for example 80 nm) is inferior (e.g. the structure exhibiting evidence of n-doped nanocrystalline silicon) to the crystal quality at lower thickness, for example 20 nm (e.g. the structure exhibiting evidence of n-doped quasi-epitaxial silicon). This is why we call this as quasi-epitaxial Si film. While the crystal planes in less than 50 nm thickness of the film (in regions 150) clearly follow the crystal planes in the substrate 22, lattice images of different orientations at higher thicknesses (in regions 150) show that the crystal quality has degraded. This suggests that the growth of the doped emitter layer 23 is similar to the epitaxial growth initially however the growth mechanism gradually turns into nanocrystalline-like growth at higher thicknesses. It is surmised that growth of the doped emitter layer 23 may tend to amorphous Silicon in the extreme when the effects of propagation of the substrate 22 crystal lattice structure dissipates entirely. It is recognized that the transition between the epitaxial-like growth to nanocrystalline-like growth can be very gradual and there can be no well-defined boundary between the material phases. Meanwhile, the transition can depends upon the growth conditions and the crystal orientation of the substrate 22.

Another aspect of the quasi-epitaxial growth of the doped emitter layer 23 is the substrate 22 orientation independence of this growth rate. The fabrication 200 process is applicable on mc-Si substrates, as well as CZ and FZ crystalline silicon substrates. FIG. 12c shows the HRTEM picture of the doped emitter layer 23 on a grain boundary (GB) region 42 of the (p) mc-Si substrate 22. The crystal orientations on different sides of the GB are different. The HRTEM picture 30 shows that the atomic arrangement in the doped emitter layer 23 follows the atomic arrangement of the mc-Si substrate 22 in both sides of the GB. This suggests that the epitaxial growth of the initial (n+) doped emitter layer 23 is independent of the crystal orientation of the substrate 22. Further analyses showed that the developed doped emitter layer 23 have very good crystallinity at least up to 50 nm thickness, for example. Therefore, the doped emitter layers 23 of about 45 nm-55 nm, for example, are expected to show very desirable electrical conductivities (as compared to less desirable (n+) a-Si:H films) because the doped emitter layers 23 are expected to show higher electron mobility as well as much higher doping efficiency.

Electrical Properties

The conductivity of the doped silicon layer 23 can be extremely high. This proves that despite the low temperature nature of the fabrication process 200 (see FIG. 15) of the environment 100, the doping efficiency of the doped silicon layers 23 can be very high. Also, the high conductivity of the doped silicon layers 23 shows that despite the high concentration of phosphorous atoms and some evidence of distorted crystal structure (see FIGS. 5 and 12a,12b) in the region 152 of the doped silicon layer 23, the carrier mobility is remains desirable. The conductivity of the doped silicon layer 23 is comparable to the conductivity of highly doped Si materials obtained by high temperature diffusion, ion implantation or LPCVD. But it must be noted that the doped silicon layer 23 are obtained by about 600 C less in temperature than its high temperature counterparts.

Let's compare the conductivity of the doped silicon layer 23 with the conductivity of highly doped amorphous silicon and micro (or nano) crystalline Si films that are obtained at low temperatures using PECVD or HWCVD techniques. The conductivity of the doped silicon layers 23 is about 5 orders of magnitude more than highly doped a-Si films and one to two orders of magnitude more than the conductivity of the doped micro (nano) crystalline Si thin films.

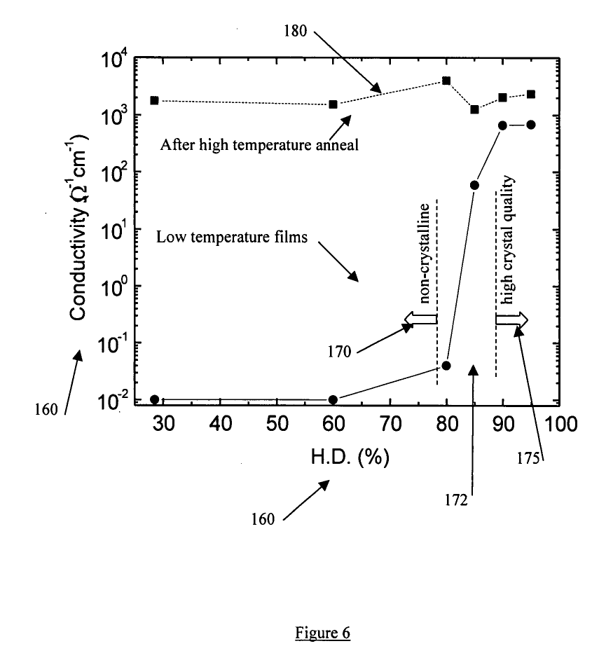

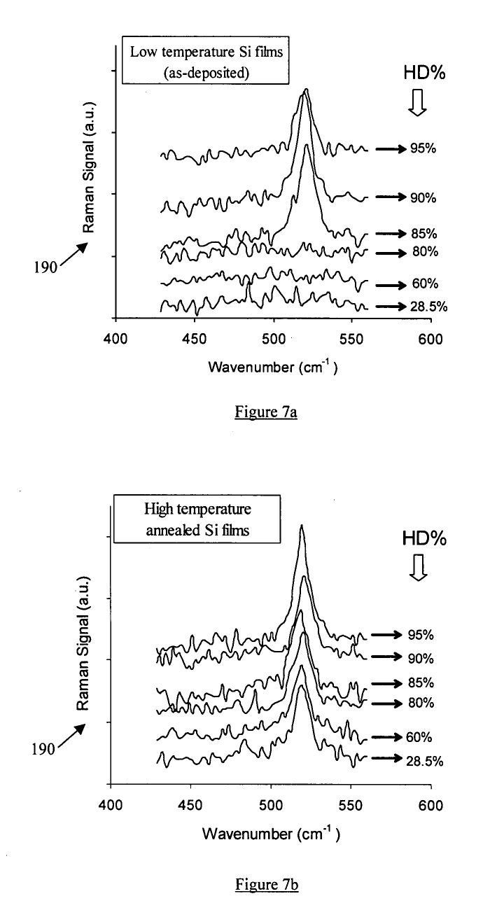

Referring to FIG. 7a, shown is the UV Raman spectra 190 of the as-deposited (low temperature 300° C.) doped PECVD doped silicon layer 23 formed under various hydrogen dilutions (HD). Raman peaks corresponding to crystalline structure are obvious in the doped silicon layer 23 with high HD (>85%). FIG. 7b shows the UV Raman spectra 190 of the doped silicon layers 23 that underwent a high temperature (750° C.) annealing after the CVD deposition. After the high temperature annealing, the peaks correspond to crystalline Si appears irrespective of HD.

Accordingly, FIGS. 7a and 7b show the UV Raman spectra 190 of the silicon doped silicon layers 23. The Raman measurements were performed at very short wavelengths (328 nm). Because of the small penetration depth of the UV signal in silicon (<10 nm) the measured signal originates from the surface region of the doped silicon layers 23. FIG. 7a shows the UV Raman spectra 190 of the as-deposited (low temperature 300° C.) doped CVD doped silicon layers 23 formed under various hydrogen dilutions (HD). The experiment showed that the doped silicon layers 23 deposited under low HD conditions did not show any Raman peak at 520 cm−1 while the doped silicon layers 23 grown with HD values more than 85% showed a Raman peak at 520 cm−1. This further conforms the quasi-epitaxial growth of the low-temperature (n+) doped silicon layers 23 using relatively high HD (>85%) and non-crystalline doped silicon layers 23 growth using low HD (<80%). This result is completely inline with the results obtained from the electrical conductivity measurements of FIG. 6.

FIG. 7b shows the UV Raman spectra 190 of the doped silicon layers 23 after subjecting them to a high temperature (750° C.) annealing following the PECVD deposition. The Raman peak at 520 cm−1 is observed for all of the samples irrespective of the HD during the PECVD deposition. This shows that the high temperature anneal caused a solid phase recrystallization in all the doped silicon layers 23. This result also supports the results of the conductivity measurement of FIG. 6.

Accordingly, the high crystal quality of the doped silicon layers 23 makes their optical absorption properties very close to that of crystalline silicon. Therefore while deploying the doped silicon layers 23 on c-Si substrates 22 for device applications, there could be much less restrictions on the maximum thickness of the doped silicon layers 23 from an optical point of view (whereas, noncrystalline Si films need to be limited in thickness). This flexibility in doped silicon layers 23 thickness can enhance the chances of employing low-cost metallization techniques such as screenprinting in the case of doped silicon layers 23.

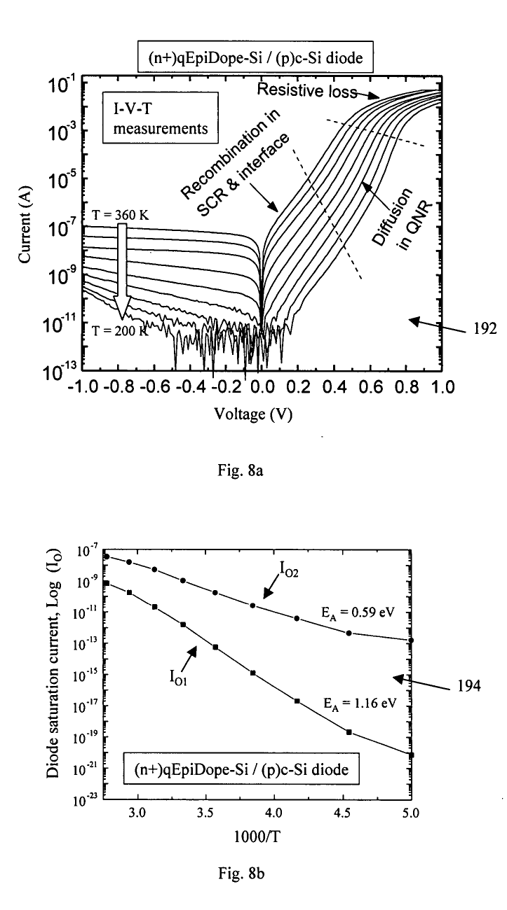

Referring to FIG. 8a, a good quality junction between the (n+) doped silicon layer 23 and the (p)c-Si substrate 22 is also usefull because the quality of the solar cell (e.g. silicon device 21) depends on the quality of the n+p diode. FIG. 8a shows a dark current-voltage-temperature (I-V-T) characteristics 192 of a 16 mm2 (n+)-Si/(p)c-Si diode having Al contacts on both sides of the diode. The I-V characteristic of the solar cell 21 can be modeled by double diode model where diode-1 models the medium forward bias regime and diode-2 models the low forward bias regime. The first diode saturation current density at room temperature (300K) is 7.1 pA/cm2 (extracted from FIG. 8a). Saturation currents 194 of the first and the second diodes, I01 and I02, are shown in FIG. 8b in logarithmic scale versus 1000/T. The activation energies (EA) of the I01 and I02 were calculated from the slope of the IO versus 1000/T curves of FIG. 8b and EA values of 1.16 eV and 0.59 eV were obtained respectively for the first and second diodes. The activation energy of 1.16 eV, very close to the band gap of crystalline Si (1.12 eV), in the medium forward bias region indicates that the diffusion in quasi-neutral region is the main current transport mechanism in this regime. However, the activation energy of 0.59 eV, very close to the half of the c-Si band gap (0.56 eV), in the low forward bias regime indicates that the recombination in the space charge region and interface is the main current transport mechanism in this regime. Meanwhile, the average ideality factor of 1.84 in this regime shows that the energy levels of the active defects (in the space charge region and in the interface) are distributed inside the band gap of the c-Si substrate 22. The current-voltage-temperature measurement of the diode shows that the effect of the interface can be neglected for solar cell 21 applications because solar cells 21 work normally in medium forward bias (0.4<V<0.6) conditions. This means the interface between the (n+) Si emitter layer 23 and the (p)mc-Si substrate 22 is photovoltaically clean and can be employed for fabrication of solar cells 21, without any additional interfacial passivation layers.

Conclusions

It is recognized that the doped silicon layer 23 process of FIG. 4 and related Figures can be used in any electronic device 21 application where a high quality pn junction is to be formed under low temperature conditions (e.g. around 300 C). Further, it is recognized that both n- and p-type doping can be employed. Further, it is an advantage of the doped silicon layer 23 that high quality junctions between highly doped silicon layers 23 and crystalline silicon substrates 22 can be obtained without use of ultra thin, intrinsic buffer layers as has been used in some hetero-junction cell processes. Further, the thickness of the doped silicon layer 23 can be between 40 nm-100 nm, which is a few times higher than the amorphous silicon emitters used in hetero-junction devices. The high crystallinity (close to crystalline silicon) of the doped silicon layer 23 may not impose an upper limit on the doped silicon layer 23 thickness on the basis of optical absorption. Further, it is recognized that thicker doped silicon layers 23 can also make the use of cost-effective metallization schemes such as screen-printing. A potential advantage of the doped silicon layer 23 is that a very simple solar cell device 21 can be fabricated at low temperature without use of the TCO layer. Further, the low temperature process used in the chamber 104 of a CVD apparatus, an example of which is PE. Furthermore, the low temperature nature of the fabrication process 200 can make it ideally suitable for defective (low cost) substrate 22 too. The crystal defects in the substrates 22 can require defect passivation by hydrogen for the low temperature environment 100, where it is recognised that high process temperatures lead to hydrogen out-diffusion thereby losing the passivation effect. In the solar cells fabricated by the fabrication method 200, the doped silicon layer 23-Si substrate 22 interface can provide a high quality pn junction inhibiting the need for additional interfacial (intrinsic) passivation layers, while the highly conductive nature of the doped silicon layer 23 can inhibit the need for the use of any transparent conductive oxide films. Further, it is recognized that the region(s) 150, 152 can also contain crystal defects including amorphous silicon structures. Further, it is recognized that the atoms in the vapour of the chamber 104 can be other than as described (e.g. other sources for Si, dopants, and excess hydrogen, as desired).

Operation of the Deposition Environment 100

Referring to FIG. 14, the doped silicon layers 23 of the silicon devices 21 can be prepared by CVD (e.g. PE, HW, hot wire) at low temperature (e.g. less than 350° C.).

Referring to FIG. 4, the substrates 22 can be of different grade qualities as measured using excess carrier lifetime (measured using microwave photoconductivity decay on a Semilab WT-2000 machine). For example, the selected Si material of the silicon substrate 22 can be material such as but not limited to: multi-crystalline silicon; single crystalline silicon; ribbon crystalline silicon; and powder formed silicon. Further, the excess carrier lifetime of the silicon substrate 22 for the respective Si material can be selected from such as but not limited to: 1 to 10 micro seconds; 10 to 20 micro seconds; 30 to 50 micro seconds; 50 to 70 micro seconds; 70 to 90 micro seconds; 90 to 110 micro seconds; and greater than 110 micro seconds.

Further below, discussed are three fabrication sequences; LT Process I, LT Process II, and LT Process III for low cost manufacture of solar cells 21, as a further embodiment of the fabrication process 200 of FIG. 15. For example, process I,II could be a suitable fabrication technique for low quality silicon substrates 22 (with excess carrier lifetime in the range of 1-10 μsec) with thickness of 150-200 μm. Process III is similar to process I,II with only one major difference, a short medium temperature (e.g. about 750° C.) rapid thermal annealing step is utilized to (i) form a back surface field structure, and to (ii) improve the conductivity of the (n+) doped silicon layer 23. Because of the formation of the back surface field structure, process III is suitable for medium and high quality silicon substrates, for example, (with excess carrier lifetime in the range of 50-100 μsec.

Fabrication Process 200

Referring to FIGS. 14 and 15, shown is the fabrication process 200 using the environment 100 of FIG. 4. The fabrication process 200 is a low temperature process for depositing a doped silicon layer 23 on a silicon substrate 22 of a selected grade, the silicon substrate 22 for functioning as a light absorber and the doped silicon layer 23 for functioning as an emitter of the silicon device 21. The process 200 has the following steps, optionally a step 202 such that the substrate 22 surface is made suitable for promoting crystalline film growth. Cleaning the substrate 22 by wafer surface treatment by HF, for example can do this, and a fast pump down of the PECVD chamber 104 to high vacuum before deposition inhibits oxide formation on the cleaned substrate 22 surface. Further, pre-deposition of the surface treatment of the substrate 22 by a soft hydrogen plasma in the chamber 104 can be done as is known in the art. It is recognised that preparation of the substrate 22 surface prior to growth of the doped emitter 23 layer can be done external to the environment 100 by a third party cleaner, not shown. A further embodiment of the surface preparation can be such that the crystalline Si substrates 22 are cleaned using a standard RCA cleaning technique and then go through a short (5 sec) HF dip (2% HF in DI water). The substrates 22 are then blow-dried by nitrogen gas before being loaded in the chamber 104. After getting proper base pressure (e.g. 1−2×10−6 Torr) for film deposition, a very short (e.g. 2 min) and soft hydrogen (about 5 mW/cm2) plasma treatment is performed on the substrate 22 surface.

Next, a step 204 the silicon substrate 22 is positioned in the chamber 104 suitable for chemical vapour deposition of the doped silicon layer 23 on the silicon substrate 22. Next, at step 206, a plurality of process parameters 102 are specified for adjusting growth of the doped silicon layer 23, such that the plurality of process parameters 102 includes at least a first process parameter of a process temperature between 190 and 360 centigrade and a second process parameter of a hydrogen dilution level for providing excess hydrogen atoms to affect a layer crystallinity of the atomic structure of the doped silicon layer 23. Other process parameters 102 can include plasma RF power, process pressure, and flow rates of the atoms with respect to the external surface of the substrate 22 in the chamber 104, depending upon the type of CVD process followed.

Next at step 208 the external surface 114 of the silicon substrate 22 is exposed in the chamber 104 to a vapour including silicon atoms Si, dopant atoms (e.g. P, B) and the excess hydrogen atoms H (see FIG. 4), the atoms for use in growing the doped silicon layer 23. At step 210, the growth of the doped silicon layer 23 is done on the external surface 114 to form an interface between the doped silicon layer 23 and the silicon substrate 22, such that doped silicon layer 23 includes first atomic structural regions having a propagated quality of layer crystallinity from the crystal structure of the substrate 22.

Subsequently, the produced silicon wafer 21 can be used to manufacture a number of different PV or other electronic silicon wafer based devices, examples of which are shown with respect to FIGS. 9a,b,c and 10a,b,c.

Using the new doped silicon layers 23 and the pn junctions formed with it, three solar cell fabrication process sequences, “LT Process I”, “LT Process II”, and “LT Process III”, are described. All the fabrication steps in LT-Process I and II are carried out at low temperature (e.g. <400° C.). The sequences LT-Process I and II can be ideally suitable for low-quality silicon substrates 22 that would otherwise degrade if subjected to even moderately high temperatures (e.g. typical annealing temperatures), and also for defective Si substrates 22 that undergo pre-process hydrogenation for bulk defect passivation. “LT Process III” can be suited for those Si substrates 22 that can stand up to moderately high temperatures (e.g. around 700-800° C.), but that would degrade if subjected to very high temperatures (e.g. greater than 900° C.). All the process steps in LT Process III are carried out below a temperature of 750° C., for example.

It is recognized that all three processes I,II,III can be suitable for low-cost (low-quality) Si substrates 22 whose material quality would degrade if subjected to multiple high temperature excursions (greater than 850-900° C.). However, the new processes I,II,III can also be suited for high quality Si substrates 22 as well (e.g. electronics grade silicon wafers), and can yield high conversion efficiencies. The simplicity and the low-thermal budget nature of the processes can also contribute in cost-reduction. A selected grade of the silicon substrate can be: multi-crystalline silicon; single crystalline silicon; ribbon crystalline silicon; or powder formed silicon. A quality of the substrate 22 crystal structure of a selected grade for excess carrier lifetime can be chosen such as but not limited to: 1 to 10 micro seconds; 10 to 20 micro seconds; 30 to 50 micro seconds; 50 to 70 micro seconds; 70 to 90 micro seconds; 90 to 110 micro seconds; and greater than 110 micro seconds, for example.

Fabrication Process 300

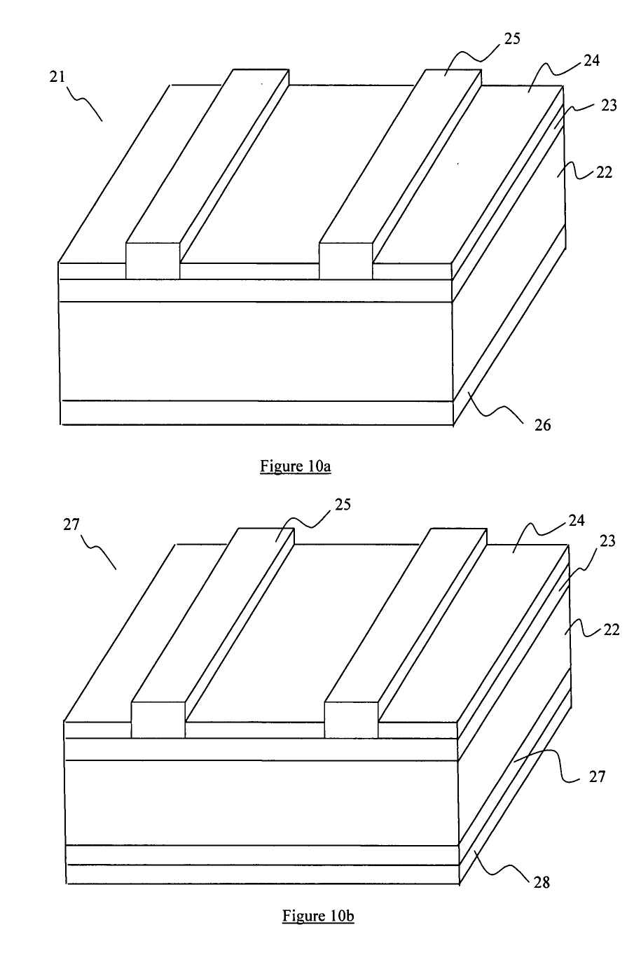

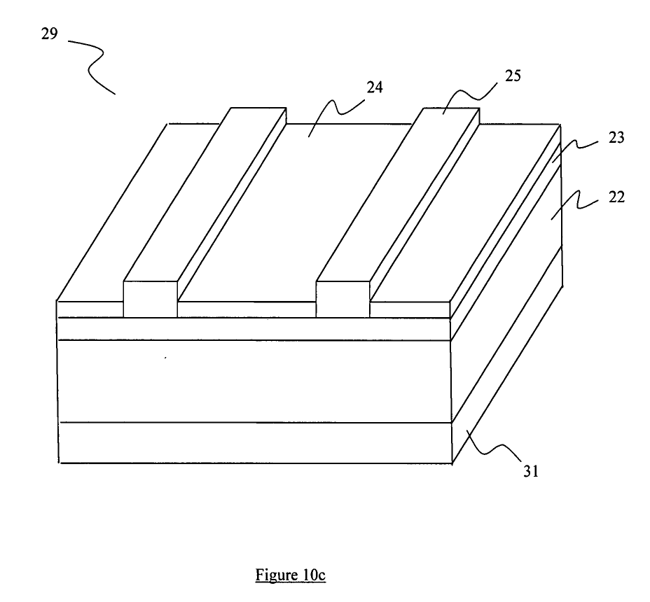

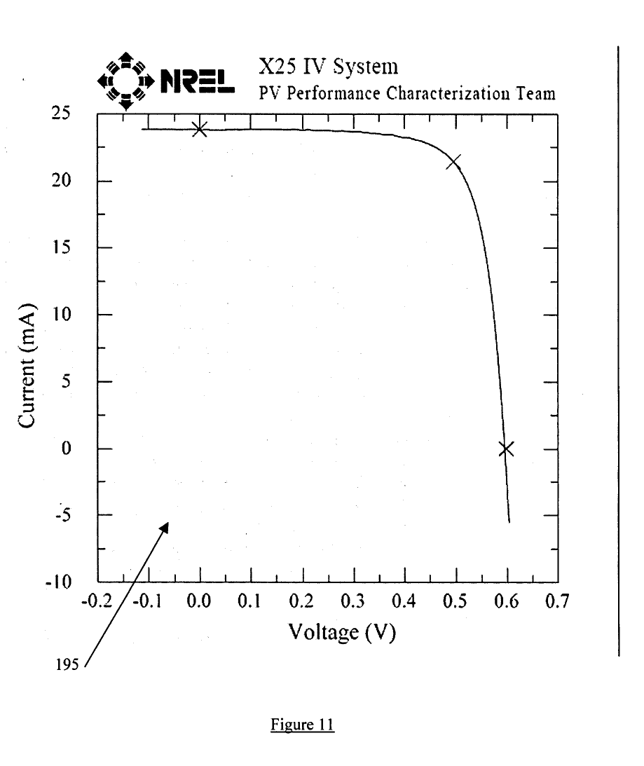

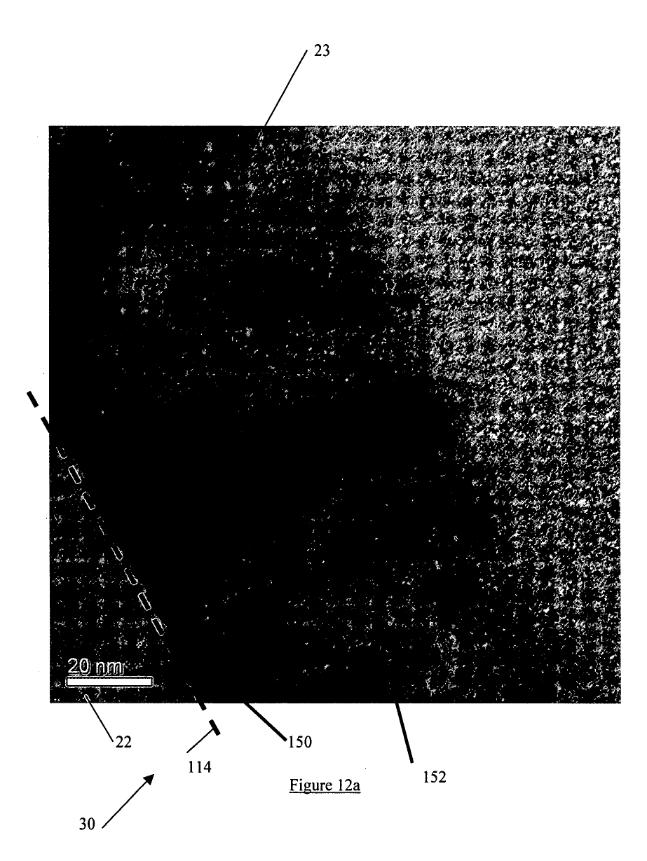

Referring to FIGS. 9a and 10a, LT Process I is the basic process sequence 300, where doped silicon layer 23 is deposited onto a c-Si substrate 22 to form the pn junction device 21. This process 300 can be specifically suitable for silicon substrates 22 whose minority carrier diffusion length is small (compared to wafer thickness), for example low-cost Si materials that have high defect densities and the ones that would further degrade when subjected to multiple high temperature excursions. The low temperature nature (e.g. <360° C.) of LT Process I also provides for an optional pre-process hydrogen defect passivation to be applied to the wafers 22. When the minority carrier diffusion length is low the back surface field won't be of much help, and hence the process is kept short and simple. The high conductivity of the doped silicon layer 23 helps to eliminate the need for TCO, and the highly crystalline nature of the doped silicon layer 23 provides a suitable abrupt pn junction.

FIG. 9a illustrates the solar cell fabrication sequence 300 for LT Process I. The corresponding schematic of the solar cell device 21 is shown in FIG. 10a. The solar cell 21 fabrication starts with standard cleaning 302 of the crystalline silicon substrate (p or n type), 22. The substrate 22 can be single crystalline silicon (CZ-Si or FZ-Si), multicrystalline silicon or silicon ribbon, for example. After standard cleaning 302 process the native oxide of the silicon substrate 22 is etched away by diluted hydrofluoric acid solution (2% HF in DI water). The doped silicon layer 23 (e.g. n+ or p+ type) is then formed 304 on the silicon substrate 22 using PECVD of silane and phosphine (or diborane in the case of p-type films) in presence of sufficient amount of hydrogen. The process conditions of the parameters 102 (see FIG. 4) is such that highly conductive doped silicon layer 23 is obtained. The thickness of the doped silicon layer 23 may vary between 10 nm-40 nm-100 nm, for example. A front side grid metallization 25 is performed 306 using PVD techniques (sputtering or evaporation). It is noted that the front metallization 25 is formed directly on the doped silicon layer 23. Since the doped silicon layer 23 conductivity is high, there can be no need to employ any transparent conductive oxides (TCO). Antireflective coating layer (or layers) 24 with appropriate thickness is (are) deposited 310 using PECVD of silane, ammonia, and/or nitrous oxide as gas phase precursors at low temperature (about 250° C.). Before deposition 308 of backside Al contact 26, a very short (1-2 sec) diluted HF (1%) dip process followed by a dip in 30 sec DI water can be conducted to remove native oxide in the backside of the wafer 22. The backside Al layer 26 with sufficient thickness (2-3 μm) is deposited 308 on the backside of the solar cell 21 using a PVD technique, for example. To achieve highest level of simplicity, no back surface field structure has been utilized in LT Process I. Basically there can be no need for BSF structure if a low quality Si substrate is used. The minority carrier diffusion length for low quality materials is often less than 200 μm, a typical value for the substrate thickness. This suggests that the use of BSF structure may not be necessary because the effective excess carrier lifetime is mainly dominated by the bulk of the Si substrate 22 rather than the back surface.

Fabrication Process 320

Referring to FIGS. 9b and 10b, with LT Process II, high quality Si substrates 22, thinner substrates 22 (diffusion length>>wafer thickeness), or those substrates 22 with their carrier lifetimes increased by hydrogen passivation can yield to solar cells 21 with high conversion efficiencies. This fabrication process 320 uses the doped silicon layer 23 for the formation of both the emitter 23 (n+p or p+n) and BSF 27 (p+p or n+n). Both front 25 and rear 28 metallizations can be formed directly on top of the doped silicon layers 23, 27. The process 320 is entirely a at low temperature (e.g. <360° C.).

Referring again to FIGS. 9b and 10b, when the low cost (or defective) substrate 22 quality can be improved by pre-process defect passivation techniques such as hydrogenation, or when thinner wafers (<150 μm) are used, then the need for a BSF 28 can become useful while the stringent requirement for low-temperature process still holds. The LT Process II can be suited for such cases. FIG. 9b illustrates the fabrication steps 320 involved in the LT Process II. The corresponding solar cell device 27 is schematically represented in FIG. 10b. The only difference in LT Process II is that, following the deposition of the doped emitter 23 (n+ or p+ type) another qEPiDope Si film (p+ or n+ type) 27 is deposited 326 on the back side of the substrate 22 to function as BSF. A rear aluminum contact 28 is deposited 312 directly on the doped Si BSF layer 27. The LT Process II can provide high conversion efficiencies for either high lifetime wafers, or defect passivated wafers, or thinner wafers, while keeping all the process steps low temperature.

Fabrication Process 400

Referring to FIGS. 9c and 10c, the LT Process III 400 is shown where in addition to the doped Si emitter 23, a short time (e.g. <1-2 minutes), medium temperature (e.g. 700-750-800° C.) thermal anneal 408 is employed to cause a solid phase recrystallization of the emitter 23 and to form an aluminum alloyed BSF 31 simultaneously. In this process the low temperature formation of the thin film emitter 23 has a wider process window of variations, i.e., the film 23 growth rate can be increased at the expense of film 23 crystallinity. The subsequent thermal anneal step 408 can improve the crystallinity and electrical conductivity in the emitter 23. With the Al-alloyed BSF process 408, a separate boron doped p+ BSF film may not be necessary. Further, since the Al film 31 that is deposited on the rear surface of the device 29 prior to the short thermal anneal 408 is thick enough (3-5 μm), there may be no need for another metal deposition process for rear contact.

The LT Process III 400 is illustrated in FIG. 9c, and, compared to LT Process I, it involves a very short (<1-2 minute), medium temperature thermal anneal 408 in order to simultaneously (i) form the BSF, and (ii) to improve the crystal quality and conductivity of the emitter 23. The process 400 therefore is still a low thermal budget process. It provides a simple alternative for substrates that require a BSF and that do not degrade after medium temperature thermal anneal. The resulting device structure 29 from LT Process III is schematically represented in FIG. 10c. In this process 400, the low temperature PECVD Si emitter (n+ type) 23 is deposited 304 on to the p-type c-Si substrate 22 followed by deposition 406 of a 3-5 μm aluminum film 31 on the rear side of the wafer 22. The wafer 22 then undergoes 408 a short time (<1 minute) rapid thermal anneal at 750° C. In this process, an Al-alloyed p+ BSF is formed, and, at the same time the crystallinity and conductivity of the emitter 23 are improved. As has been evidenced by the conductivity (FIG. 6) and Raman (FIG. 7b) measurements, the short-time, medium temperature anneal can improve the conductivity and crystal quality of the emitter 23, irrespective of the HD. It should be noted here that the doped silicon layers 23 that already have a high crystal quality and electrical conductivity may not need an improvement by the medium temperature anneal. However, in order to achieve as-deposited (unannealed) doped silicon layers 23, certain conditions such as HD and appropriate process parameters 102 should be followed. The LT Process III offers a wider window for process variations, so that even a sub-quality doped silicon layers 23 can be improved by the process 400. Further, the film growth rate is somewhat slowed down by increased HD. Therefore, in cases where having a high growth rate is useful, one can reduce the HD and still improve the film quality by using LT Process III for suitable substrates 22 of sufficient quality. Also, since the rear metal 31 is a relatively thick Al (3-5 μm) film, after the thermal anneal part of the Al is consumed in the formation of alloyed p+ BSF, the remaining metal will act as rear metal contact 31, thereby helping to eliminate the need for metal contact formation for a second time. The aluminum BSF step replaces boron BSF, i.e. eliminate the (p+) Si BSF step compared to the LT Process II. The front metal 25, and the antireflection layer 24 can be employed similar to LT Process I.

The LT Process I, II, and III, while being ideally suited low-cost Si substrates 22 of different levels of quality, it should be noted that LT Process II and III will also yield high efficiencies on high quality single crystalline Si wafers 22.

One of the elements of the processes 200,300,320,400 is the low temperature silicon doped layer 23. As part of the initial experimental verifications of the process steps, the fill factor of the device 21 fabricated following LT Process I without employing the TCO layer was found to be 75%, thus demonstrating that resistive losses are inhibited in the emitter. This also confirmed the findings of our material level characterization. The LT Process I test cell was a 1 cm2 device built on a relatively low quality multicrystalline Si substrate 22 (lifetime<<10 μs) without surface texturing. FIG. 11 shows the current-voltage characteristic of the device 21.

We claim:

1. A low temperature method for depositing a doped silicon layer on a silicon substrate of a selected grade, the silicon substrate for functioning as a light absorber and the doped silicon layer for functioning as an emitter; the method comprising the acts of:
positioning the silicon substrate in a chamber suitable for chemical vapour deposition of the doped silicon layer on the silicon substrate, an external surface of the silicon substrate suitable for promoting crystalline film growth;
using a plurality of process parameters for adjusting growth of the doped silicon layer, the plurality of process parameters including a first process parameter of a process temperature for inhibiting diffusion of dopant atoms into the external surface of the silicon substrate, and a second process parameter of a hydrogen dilution level for providing excess hydrogen atoms to affect a layer crystallinity of the atomic structure of the doped silicon layer;
exposing the external surface of the silicon substrate in the chamber to a vapour at appropriate ambient chemical vapour deposition conditions, the vapour including silicon atoms, dopant atoms and the excess hydrogen atoms, the atoms for use in growing the doped silicon layer; and
originating growth of the doped silicon layer on the external surface to form an interface between the doped silicon layer and the silicon substrate, such that doped silicon layer includes first atomic structural regions having a higher quality of the layer crystallinity next to the interface with adjacent second atomic structural regions having a lower quality of the layer crystallinity with increasing concentrations of crystal defects for increasing thickness of the doped silicon layer from the interface.

2. The method of claim 1 further comprising the act of controlling the growth of the doped silicon layer through the plurality of process parameters to propagate a substrate crystal structure of the silicon substrate for the layer crystallinity in the first atomic structural regions.

3. The method of claim 2, wherein the layer crystallinity in the first atomic structural regions includes epitaxial growth inherited from the substrate crystal structure.

4. The method of claim 3, wherein a crystal orientation of the substrate crystal structure is similar to the layer crystallinity of the first atomic structural regions.

5. The method of claim 2, wherein the lower quality of the second atomic structural regions includes at least one of the crystal defects selected from the group comprising: grains of differing sizes; grains of differing orientations; presence of sharp grain boundaries; presence of micro or nano crystal structures; stacking faults; edge distortions; and metallic impurities.

6. The method of claim 5, wherein the higher quality of the first atomic structural regions includes at least one of the crystal defects selected from the group comprising: grains of differing sizes; grains of differing orientations; presence of sharp grain boundaries; presence of micro or nano crystal structures; stacking faults; edge distortions; and metallic impurities.

7. The method of claim 5, wherein an atomic structural transition from the substrate crystal structure through to the layer crystallinity of the second atomic structural regions has a lack of well defined boundaries between different crystal phases.

8. The method of claim 7, wherein the layer crystallinity transitions from an epitaxial phase adjacent to the interface to a nanocrystalline phase with said increasing thickness of the doped silicon layer from the interface.

9. The method of claim 2, wherein the interface forms a pn junction.

10. The method of claim 9, wherein the silicon substrate is a p type material and the doped silicon layer is an n type material.

11. The method of claim 9, wherein a thickness of the doped silicon layer is selected from the group comprising: equal to or less than 40 nm; equal to or less than 50 nm; equal to or less than 60 nm; equal to or less than 70 nm; equal to or less than 80 nm; equal to or less than 90 nm; equal to or less than 100 nm; equal to or less than 110 nm; equal to or less than 120 nm; and equal to or less than 130 nm.

12. The method of claim 9, wherein the process temperature is selected from the group comprising: between 190 and 360 centigrade; between 190 and 350 centigrade; between 190 and 325 centigrade; between 190 and 320 centigrade; between 190 and 310 centigrade; between 190 and 300 centigrade; between 190 and 290 centigrade; between 190 and 280 centigrade; between 190 and 275 centigrade; between 190 and 250 centigrade; between 190 and 225 centigrade; and between 190 and 200 centigrade.

13. The method of claim 9, wherein the selected grade of the silicon substrate is selected from the group comprising: multi-crystalline silicon; single crystalline silicon; ribbon crystalline silicon; and powder formed silicon.

14. The method of claim 13, wherein a quality of the substrate crystal structure of the selected grade for excess carrier lifetime is selected from the group comprising: 1 to 10 micro seconds; 10 to 20 micro seconds; 30 to 50 micro seconds; 50 to 70 micro seconds; 70 to 90 micro seconds; 90 to 110 micro seconds; and greater than 110 micro seconds.

15. The method of claim 2, wherein the dopant atoms are selected from the group comprising: phosphorous and boron.

16. The method of claim 15 further comprising the act of using additional process parameters of the plurality of process parameters for adjusting the growth of the doped silicon layer, the additional process parameters including plasma RF power, process pressure, and flow rates of the atoms with respect to the external surface.

17. The method of claim 16 further comprising the act of selecting the process pressure in the range of 150 mTorr to 1.1 Torr.

18. The method of claim 17 further comprising the act of selecting the plasma RF power in the range of 5 mW/cm2 to 75 mW/cm2.

19. The method of claim 18 further comprising the act of selecting the hydrogen dilution level in the range of 80 percent to 99 percent.

20. The method of claim 18 further comprising the act of selecting the hydrogen dilution level in the range of 85 percent to 95 percent.

21. The method of claim 15 further comprising the act of selecting the plurality of process parameters to facilitate a doping profile of the layer crystallinity that is uniform throughout the doped silicon layer for the first atomic structural regions.

22. The method of claim 21 further comprising the act of selecting the plurality of process parameters to facilitate a doping profile of the layer crystallinity that is uniform throughout the doped silicon layer for the second atomic structural regions.

23. The method of claim 22, wherein the majority of the dopant atoms in the doped silicon layer have 4 fold covalent bonds with their adjacent silicon atoms.

24. The method of claim 23, wherein the interface forms a pn junction.

25. The method of claim 24, wherein the pn junction is an abrupt junction with respect to a sudden concentration difference of dopant atoms between the doped silicon layer and the silicon substrate.

26. The method of claim 25, wherein the abrupt junction is at the external surface.

27. The method of claim 26 further comprising the act of forming a front metallization on an external surface of the doped silicon layer opposite the external surface of the silicon substrate.

28. The method of claim 26, wherein the chemical vapour deposition technique is PE.

29. The method of claim 26 further comprising the act of selecting the process temperature based on the selected grade of the silicon substrate.

30. The method of claim 26 further comprising the act of controlling the growth rate of the doped silicon layer based on the hydrogen dilution level.

31. The method of claim 26 further comprising the act of applying a thermal annealing step to the formed pn junction to cause a recrystallization of the layer crystallinity to decrease the level of crystal defects.

32. The method of claim 31, wherein the annealing temperature is selected between 600 and 850 centigrade.

33. The method of claim 32, wherein the annealing time is for less than 2 minutes.

34. The method of claim 26, wherein the doped silicon layer has a conductivity in the range of 500 to 3000 per Ohms cm.

35. A silicon wafer device including a doped silicon layer on a silicon substrate of a selected grade, the silicon substrate for functioning as a light absorber and the doped silicon layer for functioning as an emitter; the device comprising:
an internal surface of the silicon substrate from which originates the doped silicon layer to form an interface between the doped silicon layer and the silicon substrate, such that doped silicon layer includes first atomic structural regions having a higher quality of layer crystallinity next to the interface with adjacent second atomic structural regions having a lower quality of said layer crystallinity with increasing concentrations of crystal defects for increasing thickness of the doped silicon layer from the interface.

36. The device of claim 35 further comprising said layer crystallinity in the first atomic structural regions propagated from a substrate crystal structure of the silicon substrate.

37. The device of claim 36, wherein the layer crystallinity in the first atomic structural regions includes epitaxial growth inherited from the substrate crystal structure.

38. The device of claim 37, wherein a crystal orientation of the substrate crystal structure is similar to a crystal orientation of the layer crystallinity of the first atomic structural regions.

39. The device of claim 36, wherein an atomic structural transition from the substrate crystal structure through to the layer crystallinity of the second atomic structural regions has a lack of well defined boundaries between different crystal phases.

40. The device of claim 39, wherein the majority of the dopant atoms in the doped silicon layer have 4 fold covalent bonds with their adjacent silicon atoms.
